(19) United States
(12) Patent Application Publication
(10) Pub. No.: US 2023/0077964 A1
(43) Pub. Date: Mar. 16, 2023

(54) SEMICONDUCTOR DEVICE AND METHOD FOR MANUFACTURING SEMICONDUCTOR DEVICE

(71) Applicant: ROHM CO., LTD., Kyoto-shi, Kyoto (JP)

(72) Inventors: Katsuhiko YOSHIHARA, Kyoto-shi, Kyoto (JP); Xiaopeng WU, Kyoto-shi, Kyoto (JP)

(21) Appl. No.: 17/801,721

(22) PCT Filed: Feb. 12, 2021
(86) PCT No.: PCT/JP2021/005271

§ 371 Date: Aug. 23, 2022

(30) Foreign Application Priority Data
Mar. 4, 2020 (JP) 2020-036707

(51) Int. Cl. H01L 21/603; H01L 23/00

(52) U.S. Cl. CPC H01L 21/603; H01L 24/83; H01L 2021/6015

(57) ABSTRACT

A semiconductor device includes a semiconductor element, a first conductive member, a second conductive member, a connecting member, and a metal plate. The semiconductor element has an element obverse surface and an element reverse surface that are spaced apart from each other in a thickness direction. An obverse surface electrode is provided on the element obverse surface. The first conductive member faces the element reverse surface and is bonded to the semiconductor element. The first conductive member and the second conductive member are spaced apart from each other. The connecting member electrically connects the obverse surface electrode and the second conductive member. The metal plate is interposed between the obverse surface electrode and the connecting member in the thickness direction. The obverse surface electrode and the metal plate are bonded to each other by solid-phase diffusion.

### TECHNICAL FIELD

The present disclosure relates to a semiconductor device and a method for manufacturing a semiconductor device.

### BACKGROUND ART

Various configurations are proposed for semiconductor devices. Patent document 1 discloses an example of a conventional semiconductor device. The semiconductor device disclosed in the document includes a semiconductor element, a lead frame, a terminal, and a bonding wire. The semiconductor element is mounted on the lead frame. The lead frame and the terminal are spaced apart from each other. An electrode pad (e.g., source electrode) is disposed on an upper surface of the semiconductor element. The bonding wire is bonded to the electrode pad and the terminal and electrically connects them.

### PRIOR ART DOCUMENT

### Patent Document

Patent Document 1: JP-A-2017-5165

### SUMMARY OF THE INVENTION

### Problem to be Solved by the Invention

In the semiconductor device described in Patent Document 1, when the bonding wire is bonded to the electrode pad (e.g., source electrode) of the semiconductor element, ultrasonic vibrations may be applied with the bonding wire pressed against the electrode pad (e.g., wedge bonding). At this point, the pressing force (load) and vibrations may damage the electrode pad. This may cause damage to the semiconductor element, resulting in the lowering of reliability.

The present disclosure has been conceived in view of the above-described circumstances, and an object thereof is to provide a semiconductor device with improved reliability and a method for manufacturing the semiconductor device.

### Means to Solve the Problem

A semiconductor device provided by a first aspect of the present disclosure includes: a semiconductor element having an element obverse surface and an element reverse surface that are spaced apart from each other in a thickness direction, where the element obverse surface is provided with an obverse surface electrode; a first conductive member that faces the element reverse surface and to which the semiconductor element is bonded; a second conductive member spaced apart from the first conductive member; a connecting member electrically connecting the obverse surface electrode and the second conductive member; and a metal plate interposed between the obverse surface electrode and the connecting member in the thickness direction, wherein the obverse surface electrode and the metal plate are bonded to each other by solid-phase diffusion.

According to a second aspect of the present disclosure, there is provided a method for manufacturing a semiconductor device. The semiconductor device includes a semiconductor element having an element obverse surface and an element reverse surface that are spaced apart from each other in a thickness direction, the semiconductor element having an obverse surface electrode provided on the element obverse surface, and a conductive connecting member electrically connected to the semiconductor element. The method includes a solid-phase diffusion bonding step of bringing a metal plate into contact with the obverse surface electrode, and bonding the metal plate and the obverse surface electrode by solid-phase diffusion through heating and pressurizing; and a bonding step of bonding the connecting member to the metal plate.

### Advantages of the Invention

The semiconductor device according to the present disclosure can improve reliability. Furthermore, the method for manufacturing a semiconductor device according to the present disclosure can manufacture a semiconductor device with improved reliability.

### BRIEF DESCRIPTION OF THE DRAWINGS

FIG. 1 is a perspective view showing a semiconductor device according to a first embodiment.

FIG. 2 is a perspective view corresponding to FIG. 1 but omitting a resin member.

FIG. 3 is a plan view showing the semiconductor device according to the first embodiment.

FIG. 4 is a plan view corresponding to FIG. 3, with the resin member indicated by an imaginary line.

FIG. 5 is a plan view corresponding to FIG. 4, with two input terminals and an output terminal indicated by imaginary lines.

FIG. 6 is a partially enlarged view of FIG. 5.

FIG. 7 is a front view showing the semiconductor device according to the first embodiment.

FIG. 8 is a bottom view showing the semiconductor device according to the first embodiment.

FIG. 9 is a side view (left side view) showing the semiconductor device according to the first embodiment.

FIG. 10 is a cross-sectional view along line X-X in FIG. 5.

FIG. 11 is a partially enlarged view (partially enlarged cross-sectional view) of FIG. 10.

FIG. 12 is a plan view showing a step of a method for manufacturing the semiconductor device according to the first embodiment.

FIG. 13 is a plan view showing a step of the method for manufacturing the semiconductor device according to the first embodiment.

FIG. 14 is a plan view showing a step of the method for manufacturing the semiconductor device according to the first embodiment.

FIG. 15 is a plan view showing a step of the method for manufacturing the semiconductor device according to the first embodiment.

FIG. 16 is a plan view showing a step of the method for manufacturing the semiconductor device according to the first embodiment.

FIG. 17 is a cross-sectional view showing a semiconductor device according to a second embodiment.

FIG. 18 is a perspective view showing a semiconductor device according to a third embodiment.

FIG. 19 is a plan view showing the semiconductor device according to the third embodiment.

FIG. 20 is a cross-sectional view along line XX-XX in FIG. 19.

FIG. 21 is a partially enlarged cross-sectional view showing a first variation of a metal plate.

FIG. 22 is a partially enlarged cross-sectional view showing a second variation of the metal plate.

FIG. 23 is a partially enlarged cross-sectional view showing a third variation of the metal plate.

FIG. 24 is a partially enlarged cross-sectional view showing a fourth variation of the metal plate.

FIG. 25 is a partially enlarged cross-sectional view showing a semiconductor device according to a variation.

### MODE FOR CARRYING OUT THE INVENTION

Preferred embodiments of a semiconductor device and a method for manufacturing the semiconductor device according to the present disclosure are described below with reference to the drawings. In the following, the same or similar components are provided with the same reference signs, and redundant descriptions are omitted.

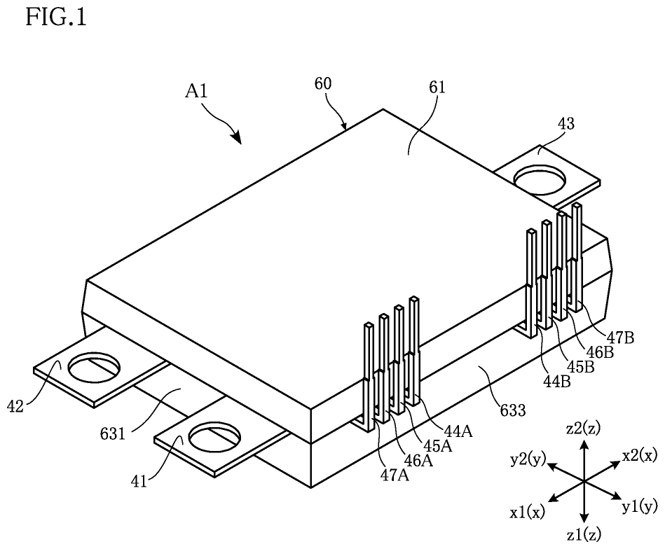

FIGS. 1 to 11 show a semiconductor device A1 according to a first embodiment. The semiconductor device A1 includes a plurality of semiconductor elements 10, a support substrate 20, a plurality of metal plates 30, two input terminals 41 and 42, an output terminal 43, a plurality of signal terminals 44A-47A and 44B-47B, a plurality of connecting members 50, and a resin member 60.

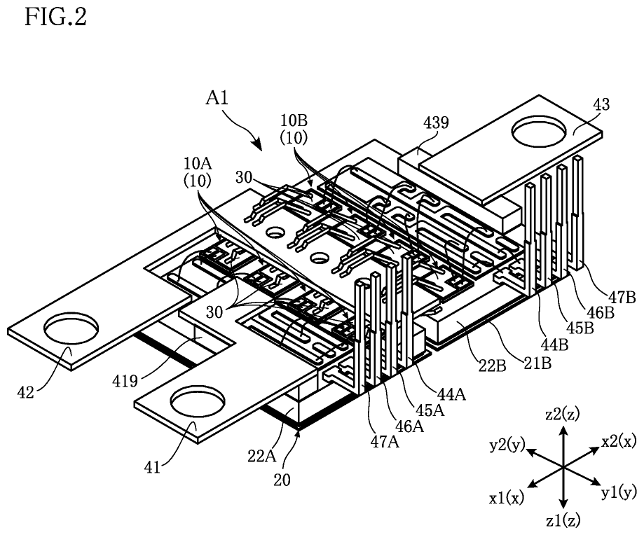

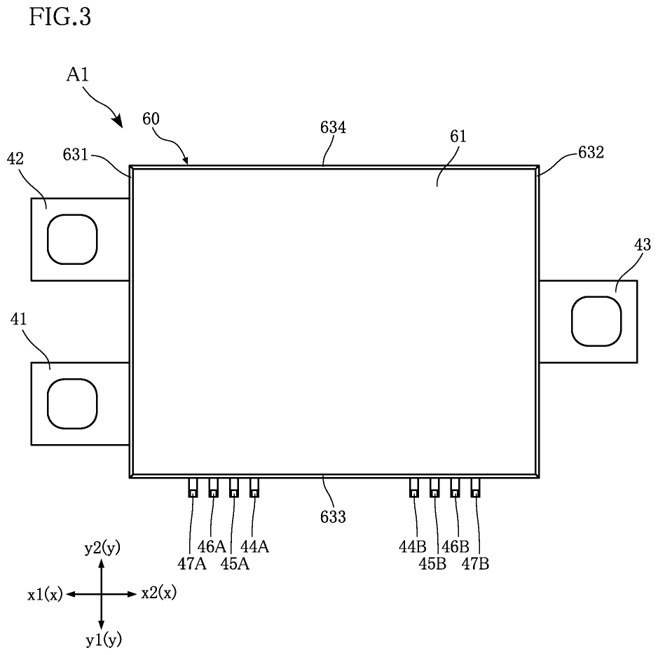

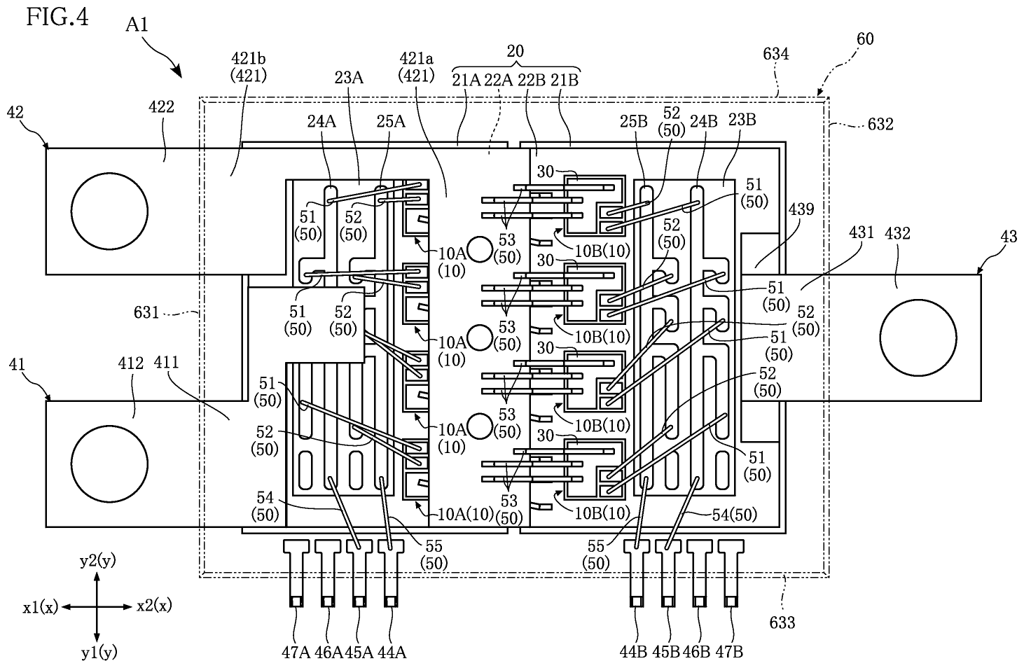

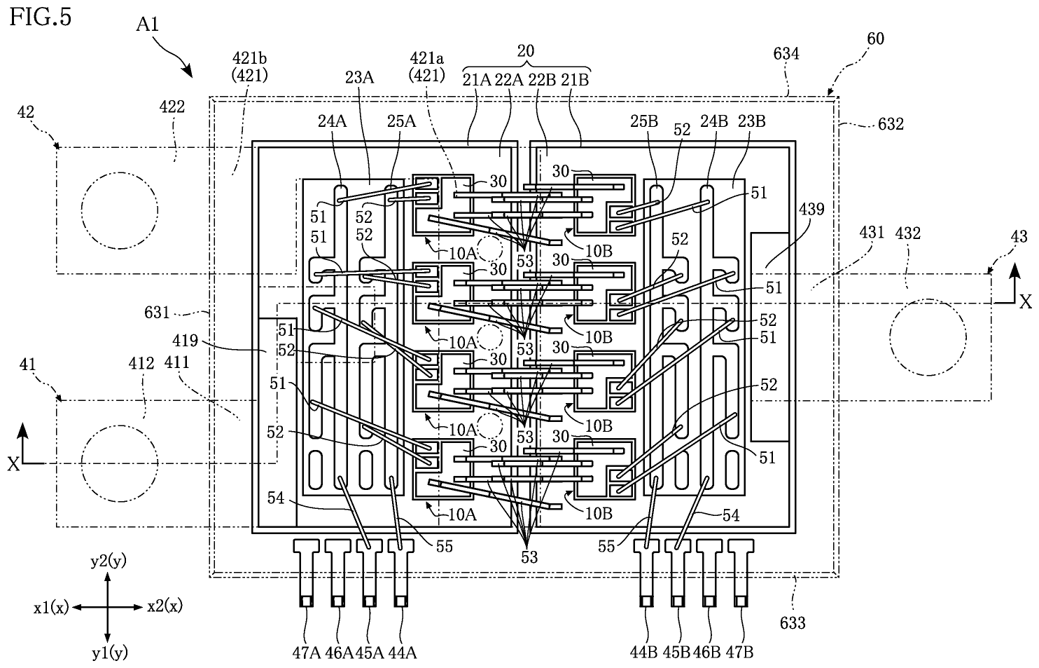

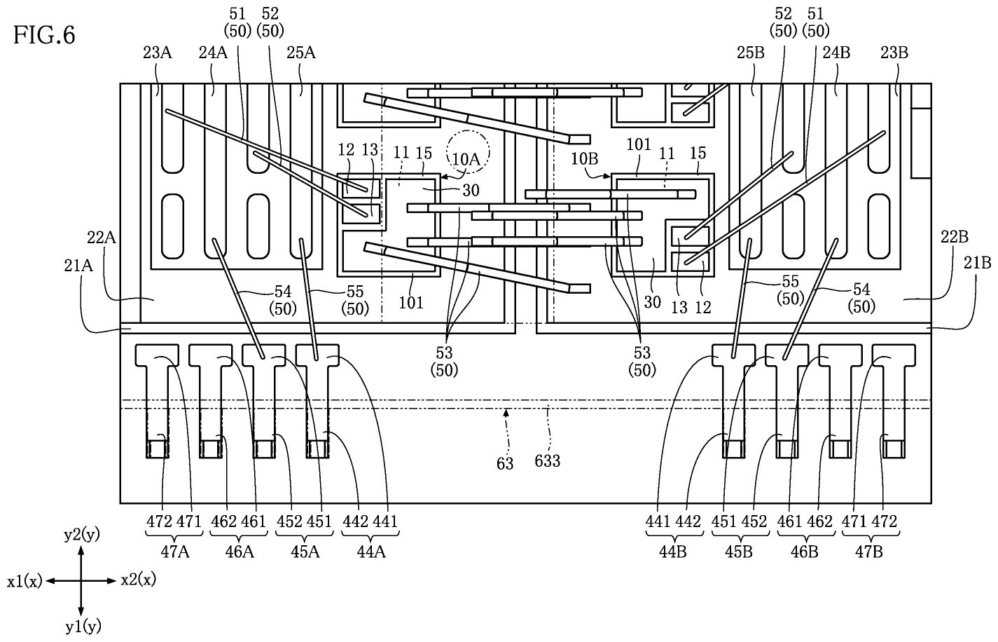

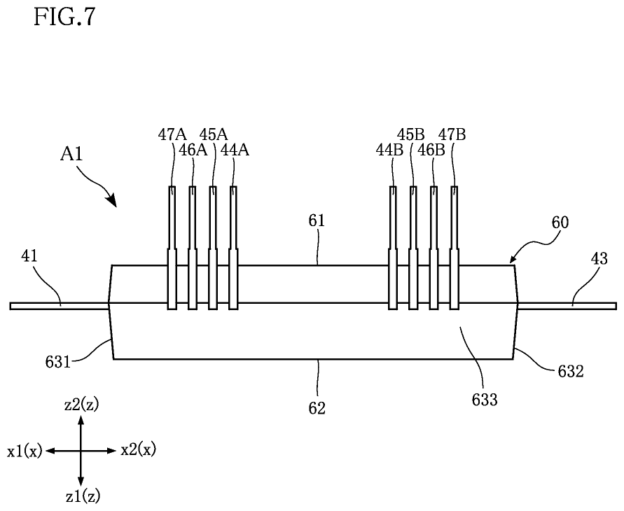

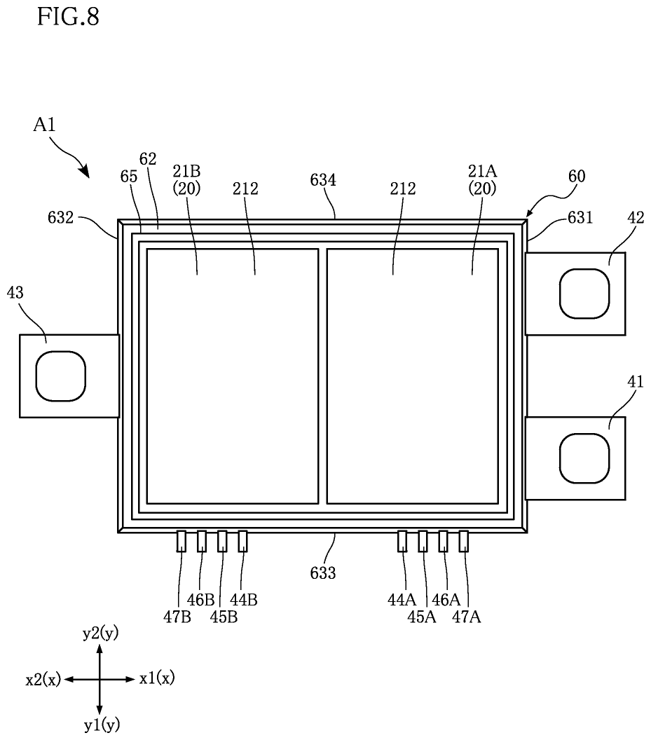

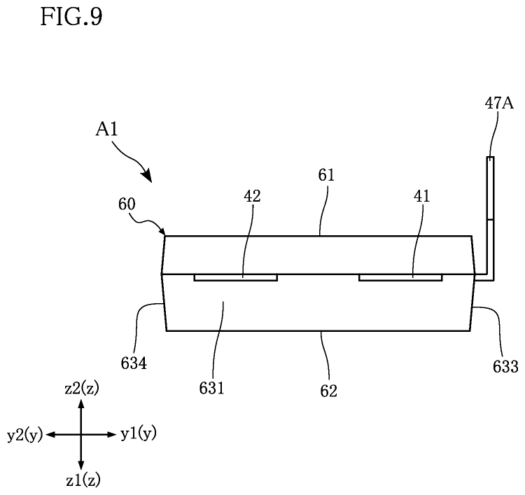

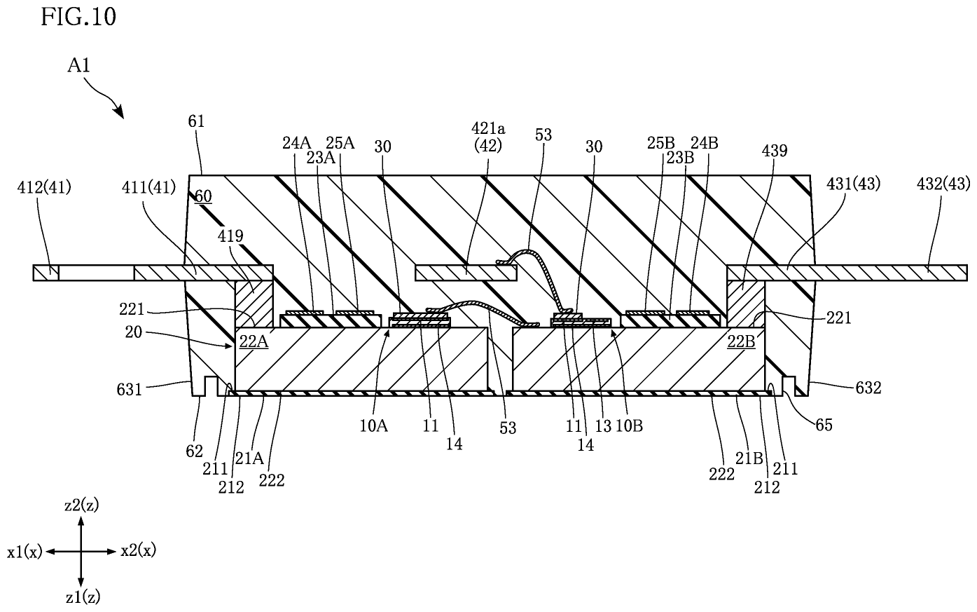

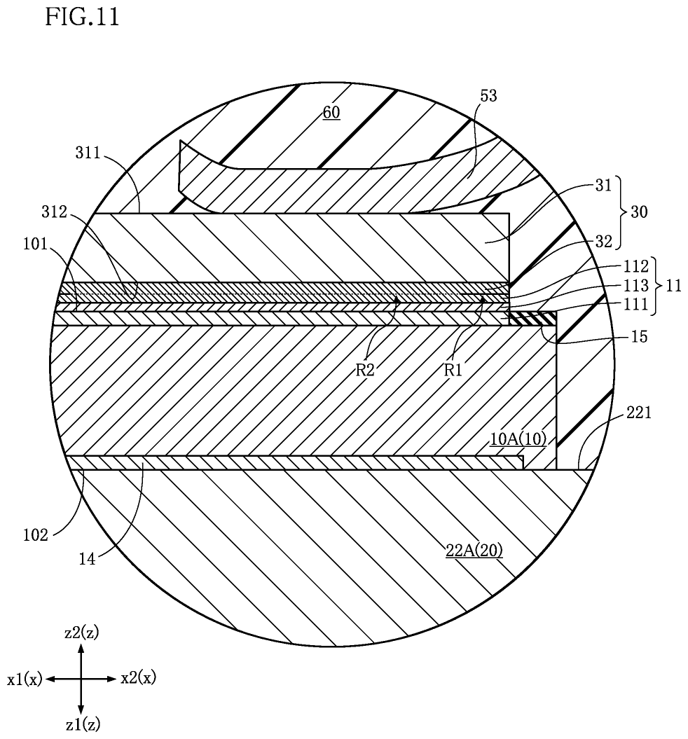

FIG. 1 is a perspective view showing the semiconductor device A1. FIG. 2 is a perspective view corresponding to FIG. 1 but omitting the resin member. FIG. 3 is a plan view showing the semiconductor device A1. FIG. 4 is a plan view corresponding to FIG. 3, with the resin member 60 indicated by an imaginary line (two-dot chain line). FIG. 5 is a plan view corresponding to FIG. 4, with the two input terminals 41, 42 and the output terminal 43 indicated by imaginary lines. FIG. 6 is a partially enlarged view of FIG. 5. FIG. 7 is a front view showing the semiconductor device A1. FIG. 8 is a bottom view showing the semiconductor device A1. FIG. 9 is a side view (left side view) showing the semiconductor device A1. FIG. 10 is a cross-sectional view along line X-X in FIG. 5. FIG. 11 is a partially enlarged cross-sectional view of FIG. 10.

For the purpose of description, three directions perpendicular to each other are defined as x, y and z directions. The z direction is the thickness direction of the semiconductor device A1. The x direction is the horizontal direction in a plan view (see FIG. 3) of the semiconductor device A1. The y direction is the vertical direction in a plan view (see FIG. 3) of the semiconductor device A1. One sense of the x direction is defined as x1 direction, and the other sense as x2 direction. Similarly, one sense of the y direction is defined as y1 direction, and the other sense as y2 direction. One sense of the z direction is defined as z1 direction, and the other sense as z2 direction. In the following description, a “plan view” is a view seen in the z direction.

Each of the semiconductor elements 10 forms the functional core of the semiconductor device A1. Each of the semiconductor elements 10 has a rectangular shape in plan view, but the present disclosure is not limited to this. The semiconductor elements 10 are power semiconductor elements such as metal-oxide-semiconductor field-effect transistors (MOSFETs). The semiconductor elements 10 are not limited to MOSFETs, and may be field effect transistors including metal-insulator-semiconductor field-effect transistors (MISFETs), bipolar transistors such as IGBTs, or other suitable transistors. The semiconductor elements 10 may also be IC chips such as LSIs, diodes, or capacitors. The semiconductor elements 10 are the same elements. The semiconductor elements 10 are n-channel MOSFETs, for example, but may be p-channel MOSFETs instead. The semiconductor elements 10 are made of a semiconductor material that mainly contains silicon carbide (SiC), for example. The semiconductor material is not limited to SiC, and may be silicon (Si), gallium arsenide (GaAs) or gallium nitride (GaN).

As shown in FIG. 11, each of the semiconductor elements 10 has an element obverse surface 101 and an element reverse surface 102. In each of the semiconductor elements 10, the element obverse surface 101 and the element reverse surface 102 are spaced apart from each other in the z direction. The element obverse surface 101 faces in the z2 direction, and the element reverse surface 102 faces in the z1 direction.

Each of the semiconductor elements 10 has a first electrode 11, a second electrode 12, a third electrode 13, a fourth electrode 14, and an insulating film 15. As shown in FIGS. 6 and 11, the first electrode 11, the second electrode 12, the third electrode 13, and the insulating film 15 are provided on the element obverse surface 101, and the fourth electrode 14 is provided on the element reverse surface 102.

The first electrode 11 is a source electrode through which a source current flows, for example. The first electrode 11 is an example of an “obverse surface electrode”. The second electrode 12 is a gate electrode that receives a drive signal (e.g., gate voltage) for driving the semiconductor element 10, for example. The third electrode 13 is a source sense electrode through which a source current flows, for example. Note that the third electrode 13 may not be formed on the semiconductor element 10. In plan view, the first electrode 11 is larger than each of the second electrode 12 and the third electrode 13, and the second electrode 12 and the third electrode 13 have substantially the same size. In the example shown particularly in FIG. 6, the first electrode 11 includes a single region. However, the first electrode 11 may be divided into multiple regions. The positional relationship between the first electrode 11, the second electrode 12, and the third electrode 13 is not limited to the example shown particularly in FIG. 6, and may be changed as appropriate. For example, the second electrode 12 and the third electrode 13 may be arranged at the center of the element obverse surface 101 in plan view, and the first electrode 11 may be arranged in a frame shape surrounding the second electrode 12 and the third electrode 13. The fourth electrode 14 is a drain electrode through which a drain current flows, for example. The fourth electrode 14 is formed over substantially the entirety of the element reverse surface 102. The insulating film 15 is electrically insulative, and surrounds the first electrode 11, the second electrode 12, and the third electrode 13 in plan view. The insulating film 15 insulates the first electrode 11, the second electrode 12, and the third electrode 13 from each other. The insulating film 15 may be formed by stacking a silicon dioxide (SiO₂) layer, a silicon nitride (SiN₄) layer, and a polybenzoxazole layer in this order on the element obverse surface 101. The configuration of the insulating film 15 is not limited to the one described above. For example, it is possible to stack a polyimide layer in place of the polybenzoxazole layer.

Each of the semiconductor elements 10 switches between a conductive state and a non-conductive state according to a drive signal (e.g., gate voltage) inputted to the second electrode 12 (gate electrode). The operation of switching between the conductive state and the non-conductive state is referred to as a switching operation. In the conductive state, a current flows from the fourth electrode 14 (drain electrode) to the first electrode 11 (source electrode). In the non-conductive state, the drain-to-source current does not flow. The semiconductor device A1 converts the source voltage inputted across the two input terminals 41, 42 to AC voltage, for example, through the switching operation of the semiconductor elements 10.

In each of the semiconductor elements 10, the first electrode 11 includes a base layer 111, a surface layer 112, and a barrier layer 113 that are stacked on each other, as shown in FIG. 11.

The base layer 111 is the main structural element for the first electrode 11. As shown in FIG. 11, the surface layer 112 and the barrier layer 113 are formed on the surface of the base layer 111 facing in the z2 direction (i.e., the surface facing in the same direction as the element obverse surface 101). The base layer 111 is made of AlCu, for example. The material of the base layer 111 is not limited to AlCu, and may be Al or an Al alloy obtained by adding an element such as Si, Mo, Ti, Ta, Ge, Ni, or Co to Al.

As shown in FIG. 11, the surface layer 112 is in contact with the metal plate 30, and is bonded to the metal plate 30 by solid-phase diffusion. The surface layer 112 is made of Ag, for example. The material of the surface layer 112 is not limited to Ag, and may be any material (e.g., Au, Zn, Cu, Hf, or Mg) that can be bonded to the metal plate 30 (a first metal layer 32 described below) by solid-phase diffusion.

As shown in FIG. 11, the barrier layer 113 is sandwiched between the base layer 111 and the surface layer 112 in the z direction. The barrier layer 113 is provided to prevent the material (e.g., Ag) of the surface layer 112 from diffusing into the base layer 111 (which may contain Al). The barrier layer 113 is made of Ni, for example. The material of the barrier layer 113 is not limited to Ni, and may be any material having a smaller diffusion coefficient than the respective materials of the base layer 111 and the surface layer 112 (e.g., Pd, Ti, Cr, W, or Ir). However, it is preferable that the material be Ni in terms of cost, versatility, process difficulty, and thermal conductivity, for example. Note that the first electrode 11 may not include the barrier layer 113, and may include the base layer 111 and the surface layer 112 directly stacked thereon.

In each of the semiconductor elements 10, the first electrode 11 is formed by stacking the barrier layer 113 and the surface layer 112 in this order on the surface of the base layer 111 facing in the z2 direction, as shown in FIG. 11. The surface layer 112 and the barrier layer 113 can be formed by sputtering or vacuum vapor deposition, for example.

The plurality of semiconductor elements 10 include a plurality of semiconductor elements 10A and a plurality of semiconductor elements 10B. In the example shown particularly in FIGS. 2 and 5, the semiconductor device A1 includes four semiconductor elements 10A and four semiconductor elements 10B. The respective numbers of semiconductor elements 10A and 10B are not limited to the above, and may be changed appropriately according to the performance required for the semiconductor device A1. The semiconductor device A1 is configured as a half-bridge switching circuit, for example. In this case, the semiconductor elements 10A constitute an upper arm circuit of the semiconductor device A1, and the semiconductor elements 10B constitute a lower arm circuit of the semiconductor device A1. Accordingly, the semiconductor elements 10A and the semiconductor elements 10B are connected in series to form bridges.

As shown particularly in FIGS. 2 and 5, the semiconductor elements 10A are mounted on the support substrate 20. In the example shown in FIG. 5, the semiconductor elements 10A are aligned in the y direction and spaced apart from each other. As shown in FIG. 10, the semiconductor elements 10A are electrically bonded to the support substrate 20 (conductive substrate 22A described below) via a non-illustrated conductive bonding member (e.g., sintered metal such as sintered silver or sintered copper, metal paste material such as silver or copper, or solder). The semiconductor elements 10A are bonded to the conductive substrate 22A such that the element reverse surfaces 102 face the conductive substrate 22A.

As shown particularly in FIGS. 2 and 5, the semiconductor elements 10B are mounted on the support substrate 20. In the example shown in FIG. 5, the semiconductor elements 10B are aligned in the y direction and spaced apart from each other. As shown in FIG. 10, the semiconductor elements 10B are electrically bonded to the support substrate 20 (conductive substrate 22B described below) via a non-illustrated conductive bonding member (e.g., sintered metal such as sintered silver or sintered copper, metal paste material such as silver or copper, or solder). The semiconductor elements 10B are bonded to the conductive substrate 22B such that the element reverse surfaces 102 face the conductive substrate 22B. In the example shown in FIG. 5, the semiconductor elements 10A and the semiconductor elements 10B overlap with each other as viewed in the x direction. However, it is not absolutely necessary for the semiconductor elements 10A and 10B to overlap with each other as viewed in the x direction.

The support substrate 20 supports the semiconductor elements 10. As shown in FIG. 10, the support substrate 20 includes a pair of insulating substrates 21A and 21B, a pair of conductive substrates 22A and 22B, a pair of insulating layers 23A and 23B, a pair of gate layers 24A and 24B, and a pair of detection layers 25A and 25B.

The pair of insulating substrates 21A and 21B are electrically insulative. Each of the insulating substrates 21A and 21B is made of a ceramic material having excellent thermal conductivity, for example. One example of the ceramic material is aluminum nitride (AlN). The insulating substrates 21A and 21B are not limited to ceramics and may be insulating resin sheets, for example. Each of the insulating substrates 21A and 21B has a rectangular shape in plan view, for example. The pair of insulating substrates 21A and 21B are aligned in the x direction and spaced apart from each other. The insulating substrate 21A is offset in the x1 direction relative to the insulating substrate 21B.

As shown particularly in FIG. 10, each of the insulating substrates 21A and 21B has an obverse surface 211 and a reverse surface 212. The obverse surface 211 and the reverse surface 212 of each of the insulating substrates 21A and 21B are spaced apart from each other in the z direction. The obverse surfaces 211 face in the z2 direction, and the reverse surfaces 212 face in the z1 direction. The obverse surfaces 211, as well as the pair of conductive substrates 22A and 22B and the semiconductor elements 10, are covered with the resin member 60. As shown in FIG. 8, the reverse surfaces 212 are exposed from the resin member 60 (resin reverse surface 62 described below). The reverse surfaces 212 are connected to a heat sink (not illustrated), for example.

The pair of conductive substrates 22A and 22B are plate-like members made of metal. The metal is copper (Cu) or a Cu alloy, for example. The pair of conductive substrates 22A and 22B constitute a conductive path to the semiconductor elements 10, together with the two input terminals 41 and 42 and the output terminal 43. The surface layer of each of the conductive substrates 22A and 22B positioned in the z2 direction is made of aluminum (Al), for example. As shown particularly in FIGS. 5 and 10, the pair of conductive substrates 22A and 22B are spaced apart from each other in the x direction. In the example shown particularly in FIGS. 5 and 10, the conductive substrate 22A is offset in the x1 direction relative to the conductive substrate 22B.

As shown particularly in FIG. 10, each of the conductive substrates 22A and 22B has an obverse surface 221 and a reverse surface 222. The obverse surface 221 and the reverse surface 222 of each of the conductive substrates 22A and 22B are spaced apart from each other in the z direction. The obverse surfaces 221 face in the z2 direction, and the reverse surfaces 222 face in the z1 direction.

As shown particularly in FIG. 10, the conductive substrate 22A is bonded to the insulating substrate 21A via a bonding member (not illustrated). The bonding member may be either conductive or insulative. In a state where the conductive substrate 22A is bonded to the insulating substrate 21A, the reverse surface 222 of the conductive substrate 22A faces the obverse surface 211 of the insulating substrate 21A. The plurality of semiconductor elements 10A are mounted on the obverse surface 221 of the conductive substrate 22A. The semiconductor elements 10A are bonded to the conductive substrate 22A via a conductive bonding member, and the conductive substrate 22A is electrically connected to the fourth electrodes 14 (drain electrodes) of the semiconductor elements 10A. In the present embodiment, the conductive substrate 22A is an example of the “first conductive member”.

As shown particularly in FIG. 10, the conductive substrate 22B is bonded to the insulating substrate 21B via a bonding member (not illustrated). The bonding member may be either conductive or insulative. In a state where the conductive substrate 22B is bonded to the insulating substrate 21B, the reverse surface 222 of the conductive substrate 22B faces the obverse surface 211 of the insulating substrate 21B. The plurality of semiconductor elements 10B are mounted on the obverse surface 221 of the conductive substrate 22B. The semiconductor elements 10B are bonded to the conductive substrate 22B via a conductive bonding member, and the conductive substrate 22B is electrically connected to the fourth electrodes 14 (drain electrodes) of the semiconductor elements 10B. In the present embodiment, the conductive substrate 22B is an example of the “second conductive member”.

The pair of insulating layers 23A and 23B are electrically insulative and made of, for example, glass epoxy resin. As shown in FIG. 5, the pair of insulating layers 23A and 23B each have a band shape extending in the y direction. As shown in FIGS. 5 and 10, the insulating layer 23A is bonded to the obverse surface 221 of the conductive substrate 22A. The insulating layer 23A is offset in the x1 direction relative to the semiconductor elements 10A. As shown in FIGS. 5 and 10, the insulating layer 23B is bonded to the obverse surface 221 of the conductive substrate 22B. The insulating layer 23B is offset in the x2 direction relative to the semiconductor elements 10B. The insulating layer 23A insulates the conductive substrate 22A from the gate layer 24A and the detection layer 25A. The insulating layer 23B insulates the conductive substrate 22B from the gate layer 24B and the detection layer 25B.

The pair of gate layers 24A and 24B are conductive and made of, for example, copper or a copper alloy. As shown particularly in FIG. 5, each of the gate layers 24A and 24B includes a band-shaped portion extending in the y direction, and a hook-shaped portion protruding from the band-shaped portion. Each of the gate layers 24A and 24B may be made of only the band-shaped portion without the hook-shaped portion. As shown in FIGS. 5 and 10, the gate layer 24A is provided on the insulating layer 23A. Some (gate wires 51 described below) of the connecting members 50 are bonded to the gate layer 24A, and the gate layer 24A is electrically connected to the second electrodes 12 (gate electrodes) of the semiconductor elements 10A via the gate wires 51. As shown in FIGS. 5 and 10, the gate layer 24B is provided on the insulating layer 23B. Some (gate wires 51 described below) of the connecting members 50 are bonded to the gate layer 24B, and the gate layer 24B is electrically connected to the second electrodes 12 (gate electrodes) of the semiconductor elements 10B via the gate wires 51.

The pair of detection layers 25A and 25B are conductive and made of, for example, copper or a copper alloy. As shown particularly in FIG. 5, each of the detection layers 25A and 25B includes a band-shaped portion extending in the y direction, and a hook-shaped portion protruding from the band-shaped portion. Each of the detection layers 25A and 25B may be made of only the band-shaped portion without the hook-shaped portion. As shown in FIGS. 5 and 10, the detection layer 25A is provided on the insulating layer 23A, together with the gate layer 24A. Some (detection wires 52 described below) of the connecting members 50 are bonded to the detection layer 25A, and the detection layer 25A is electrically connected to the third electrodes 13 (source sense electrodes) of the semiconductor elements 10A via the detection wires 52. As shown in FIGS. 5 and 10, the detection layer 25B is provided on the insulating layer 23B, together with the gate layer 24B. Some (detection wires 52 described below) of the connecting members 50 are bonded to the detection layer 25B, and the detection layer 25B is electrically connected to the third electrodes 13 (source sense electrodes) of the semiconductor elements 10B via the detection wires 52.

As shown in FIGS. 5 and 10, the gate layer 24A and the detection layer 25A are aligned in the x direction and spaced apart from each other on the insulating layer 23A. In the example shown in FIGS. 5 and 10, the detection layer 25A is closer to the semiconductor elements 10A than the gate layer 24A in the x direction. In other words, the detection layer 25A is offset in the x2 direction relative to the gate layer 24A. Note that the positions of the gate layer 24A and the detection layer 25A in the x direction may be switched around. As shown in FIGS. 5 and 10, the gate layer 24B and the detection layer 25B are aligned in the x direction and spaced apart from each other on the insulating layer 23B. In the example shown in FIGS. 5 and 10, the detection layer 25B is closer to the semiconductor elements 10B than the gate layer 24B in the x direction. In other words, the detection layer 25B is offset in the x1 direction relative to the gate layer 24B. Note that the positions of the gate layer 24B and the detection layer 25B in the x direction may be switched around.

The configuration of the support substrate 20 is not limited to the example above. For example, the two conductive substrates 22A and 22B may be bonded to a single insulating substrate. In other words, the pair of insulating substrates 21A and 21B may be formed integrally to provide a single insulating substrate. It is also possible to form metal layers on the reverse surfaces 222 of the insulating substrates 21A and 21B. The shape, size, arrangement, etc., of each of the insulating substrates 21A and 21B and the conductive substrates 22A and 22B are changed appropriately based on the number of semiconductor elements 10, the arrangement of the semiconductor elements 10, and so on.

Each of the metal plates 30 is provided on a corresponding semiconductor element 10. The metal plate 30 is bonded to the first electrode 11 of the semiconductor element 10 by solid-phase diffusion. Some (source wires 53 described below) of the connecting members 50 are bonded to the metal plate 30. In the example shown particularly in FIG. 6, each of the metal plates 30 covers almost the entire surface of the first electrode 11 of the corresponding semiconductor element 10 in plan view. However, it suffices for each of the metal plates 30 to cover at least a portion of the corresponding first electrode 11 at which the source wires 53 are bonded. Each of the metal plates 30 includes a metal base member 31 and a first metal layer 32, as shown in FIG. 11.

The metal base member 31 is the main structural element for the metal plate 30. Some of the connecting members 50 (source wires 53 described below) are bonded to the metal plate 30. The metal base member 31 is made of Cu, a Cu alloy, or a composite containing Cu, for example. The material of the metal base member 31 is not limited to a material containing Cu, and may be any material to which the connecting members 50 (source wires 53 described below) can be bonded. The thickness (dimension in the z direction) of the metal base member 31 is not particularly limited, but may be no less than 30 μm and no greater than 200 μm, for example.

As shown in FIG. 11, the metal base member 31 has a base-member obverse surface 311 and a base-member reverse surface 312. The base-member obverse surface 311 and the base-member reverse surface 312 are spaced apart from each other in the z direction. The base-member obverse surface 311 faces in the z2 direction, and the base-member reverse surface 312 faces in the z1 direction. The base-member obverse surface 311 is the upper surface of the metal base member 31, and the base-member reverse surface 312 faces the semiconductor element 10. The connecting members 50 (source wires 53) are bonded to the base-member obverse surface 311, and the first metal layer 32 is formed on the base-member reverse surface 312.

The first metal layer 32 is in contact with the base-member reverse surface 312 of the metal base member 31, and with the surface layer 112 of the first electrode 11. The first metal layer 32 is bonded to the surface layer 112 by solid-phase diffusion. As shown in FIG. 11, there are an interface portion R1 and a non-interface portion R2 formed between the first metal layer 32 and the surface layer 112, where the interface portion R1 has an interface between the first metal layer 32 and the surface layer 112, and the non-interface portion R2 has no interface between the first metal layer 32 and the surface layer 112. The non-interface portion R2 is formed as a result of molecular binding by solid-phase diffusion bonding. In addition to the interface portion R1 and the non-interface portion R2, voids may be partially formed between the first metal layer 32 and the surface layer 112. For example, the first metal layer 32 is made of Ag, which is the same material as that of the surface layer 112. The material of the first metal layer 32 is not limited to Ag, and may be any material (e.g., Au, Zn, Cu, Hf, or Mg) that can be bonded to the surface layer 112 of the first electrode 11 by solid-phase diffusion. The first metal layer 32 is formed on the surface of the metal base member 31 that faces the semiconductor element 10. The first metal layer 32 may be formed by sputtering or vacuum vapor deposition.

The two input terminals 41 and 42, the output terminal 43, and the signal terminals 44A-47A and 44B-47B are each made of a metal plate. The metal plate is made of Cu or a Cu alloy, for example. The two input terminals 41 and 42, the output terminal 43, and the signal terminals 44A-47A and 44B-47B may be formed from the same lead frame.

Source voltage is applied to the two input terminals 41 and 42. For example, the input terminal 41 is a positive terminal (P terminal), the input terminal 42 is a negative terminal (N terminal). As shown particularly in FIGS. 1 to 4, the two input terminals 41 and 42 are offset in the x1 direction in the semiconductor device A1. The two input terminals 41 and 42 are spaced apart from each other.

As shown particularly in FIG. 4, the input terminal 41 includes a pad portion 411 and a terminal portion 412.

The pad portion 411 is covered with the resin member 60. As shown in FIGS. 2, 4, 5, and 10, the pad portion 411 is electrically bonded to the conductive substrate 22A via a conductive block member 419. The material of the block member 419 is not particularly limited, and may be Cu, a Cu alloy, a composite of copper-molybdenum (CuMo), or a composite of copper-inver-copper (CIC). The pad portion 411 is bonded to the block member 419, and the block member 419 is bonded to the conductive substrate 22A. Bonding between the pad portion 411 and the block member 419, and bonding between the block member 419 and the conductive substrate 22A may be achieved by bonding with a conductive bonding member, laser bonding, or ultrasonic bonding, for example. Bonding between the pad portion 411 and the conductive substrate 22A is not only achieved by bonding with the block member 419, but also by partially bending the pad portion 411 to bond the pad portion 411 directly to the conductive substrate 22A.

The terminal portion 412 is exposed from the resin member 60. As shown particularly in FIG. 4, the terminal portion 412 extends from the resin member 60 in the x1 direction in plan view. The terminal portion 412 has a rectangular shape in plan view, for example.

As shown particularly in FIG. 4, the input terminal 42 includes a pad portion 421 and a terminal portion 422.

The pad portion 421 is covered with the resin member 60. The pad portion 421 is covered with the resin member 60, whereby the input terminal 42 is supported by the resin member 60. As shown in FIG. 4, the pad portion 421 includes a band-shaped portion 421a and a connecting portion 421b. As shown in FIG. 4, the band-shaped portion 421a has a band shape extending in the y direction, for example. Some (source wires 53 described below) of the connecting members 50 are bonded to the band-shaped portion 421a. As shown in FIG. 4, the connecting portion 421b connects the band-shaped portion 421a and the terminal portion 422. To prevent a positional deviation of the input terminal 42, an insulating block member may be provided between the pad portion 421 (e.g., connecting portion 421b) and the conductive substrate 22A.

The output terminal 43 outputs AC power (voltage) converted by the semiconductor elements 10. As shown in FIGS. 1 to 4, the output terminal 43 is offset in the x2 direction in the semiconductor device A1. The output terminal 43 includes a pad portion 431 and a terminal portion 432.

The pad portion 431 is covered with the resin member 60. As shown in FIGS. 2, 4, 5, and 10, the pad portion 431 is electrically bonded to the conductive substrate 22B via a conductive block member 439. As with the block member 419, the block member 439 may be made of Cu, a Cu alloy, a CuMo composite, or a CIC composite. However, the block member 419 may be made of a material other than these materials. The pad portion 431 is bonded to the block member 439, and the block member 439 is bonded to the conductive substrate 22B. Bonding between the pad portion 431 and the block member 439, and bonding between the block member 439 and the conductive substrate 22B may be achieved by bonding with a conductive bonding member, laser bonding, or ultrasonic bonding, for example. Bonding between the pad portion 431 and the conductive substrate 22B is not only achieved by bonding with the block member 439, but also by partially bending the pad portion 431 to bond the pad portion 431 directly to the conductive substrate 22B.

The terminal portion 432 is exposed from the resin member 60. As shown in FIG. 4, the terminal portion 432 extends from the resin member 60 in the x2 direction in plan view. The terminal portion 432 has a rectangular shape in plan view, for example.

The signal terminals 44A-47A and 44B-47B are terminals for either inputting or outputting control signals in the semiconductor device A1. Examples of the control signals include a drive signal for causing each of the semiconductor elements 10 to perform a switching operation and a detection signal (e.g., source signal) that indicates the operational state of each of the semiconductor elements 10. The signal terminals 44A-47A and 44B-47B have substantially the same shape. The signal terminals 44A-47A and 44B-47B each have an L-shape as viewed in the x direction. As shown particularly in FIGS. 1 to 8, the signal terminals 44A-47A and 44B-47B are aligned along the x direction. As shown in FIG. 9, the signal terminals 44A-47A and 44B-47B overlap with each other as viewed in the x direction. As shown particularly in FIG. 5, the signal terminals 44A to 47A are positioned adjacent to the conductive substrate 22A in the y direction in plan view, and the signal terminals 44B to 47B are positioned adjacent to the conductive substrate 22B in the y direction. The signal terminals 44A-47A and 44B-47B protrude from the surface of the resin member 60 facing in the y1 direction (resin side surface 633 described below), for example.

As shown particularly in FIGS. 5 and 6, the pair of signal terminals 44A and 44B are electrically connected to the pair of detection layers 25A and 25B, respectively, via some of the connecting members 50 (second connecting wires 55 described below). The voltage applied to the third electrode 13 of each semiconductor element 10A (i.e., voltage corresponding to a source current) is detected from the signal terminal 44A. The signal terminal 44A is a source-signal detection terminal for the semiconductor elements 10A. The voltage applied to the third electrode 13 of each semiconductor element 10B (i.e., voltage corresponding to a source current) is detected from the signal terminal 44B. The signal terminal 44B is a source-signal detection terminal for the semiconductor elements 10B.

As shown in FIG. 6, the pair of signal terminals 44A and 44B each include a pad portion 441 and a terminal portion 442. The pad portion 441 of each of the signal terminals 44A and 44B is covered with the resin member 60. As such, the signal terminals 44A and 44B are supported by the resin member 60. Each of the terminal portions 442 is connected to the corresponding pad portion 441 and exposed from the resin member 60. The signal terminals 44A and 44B are bent at the respective terminal portions 442.

As shown particularly in FIGS. 5 and 6, the pair of signal terminals 45A and 45B are electrically connected to the pair of gate layers 24A and 24B, respectively, via some of the connecting members 50 (first connecting wires 54 described below). A drive signal for driving each of the semiconductor elements 10A is inputted (e.g., gate voltage is applied) to the signal terminal 45A. The signal terminal 45A is a drive-signal input terminal (gate-signal input terminal) for the semiconductor elements 10A. A drive signal for driving each of the semiconductor elements 10B is inputted (e.g., gate voltage is applied) to the signal terminal 45B. The signal terminal 45B is a drive-signal input terminal (gate-signal input terminal) for the semiconductor elements 10B.

As shown in FIG. 6, the pair of signal terminals 45A and 45B each include a pad portion 451 and a terminal portion 452. The pad portion 451 of each of the signal terminals 45A and 45B is covered with the resin member 60. As such, the signal terminals 45A and 45B are supported by the resin member 60. Each of the terminal portions 452 is connected to the corresponding pad portion 451 and exposed from the resin member 60. The signal terminals 45A and 45B are bent at the respective terminal portions 452.

As shown particularly in FIGS. 5 and 6, the signal terminals 46A, 46B, 47A, and 47B are not connected to any of the connecting members 50 and have no electrical connection with other components. In the semiconductor device A1, the signal terminals 46A, 46B, 47A, and 47B are dummy terminals. The semiconductor device A1 may be configured without the signal terminals 46A, 46B, 47A, and

As shown in FIG. 6, the pair of signal terminals 46A and 46B each include a pad portion 461 and a terminal portion 462. The pad portion 461 of each of the signal terminals 46A and 46B is covered with the resin member 60. As such, the signal terminals 46A and 46B are supported by the resin member 60. Each of the terminal portions 462 is connected to the corresponding pad portion 461 and exposed from the resin member 60. The signal terminals 46A and 46B are bent at the respective terminal portions 462. The pair of signal terminals 47A and 47B each include a pad portion 471 and a terminal portion 472. The pad portion 471 of each of the signal terminals 47A and 47B is covered with the resin member 60. As such, the signal terminals 47A and 47B are supported by the resin member 60. Each of the terminal portions 472 is connected to the corresponding pad portion 471 and exposed from the resin member 60. The signal terminals 47A and 47B are bent at the respective terminal portions 472.

Each of the connecting members 50 electrically connects two isolated components. As shown in FIGS. 4 to 6, the connecting members 50 include a plurality of gate wires 51, a plurality of detection wires 52, a plurality of source wires 53, a pair of first connecting wires 54, and a pair of second connecting wires 55.

The gate wires 51, the detection wires 52, the source wires 53, the pair of first connecting wires 54, and the pair of second connecting wires 55 are bonding wires. The source wires 53 are made of Cu, a Cu alloy, or a composite containing Cu. The source wires 53 are Cu wires. The gate wires 51, the detection wires 52, the pair of first connecting wires 54, and the pair of second connecting wires 55 are made of Al, Au, or Cu, for example.

As shown in FIGS. 5 and 6, each of the gate wires 51 has one end bonded to the second electrode 12 (gate electrode) of a semiconductor element 10 and the other end to either one of the gate layers 24A and 24B. The gate wires 51 include those electrically connecting the second electrodes 12 of the semiconductor elements 10A and the gate layer 24A, and those electrically connecting the second electrodes 12 of the semiconductor elements 10B and the gate layer 24B.

As shown in FIGS. 5 and 6, each of the detection wires 52 has one end bonded to the third electrode 13 (source sense electrode) of a semiconductor element 10 and the other end to either one of the detection layers 25A and 25B. The detection wires 52 include those electrically connecting the third electrodes 13 of the semiconductor elements 10A and the detection layer 25A, and those electrically connecting the third electrodes 13 of the semiconductor elements 10B and the detection layer 25B. If the semiconductor elements 10 are not provided with the third electrodes 13, the detection wires 52 are bonded to the second electrodes 12.

As shown in FIGS. 5, 6, and 10, each of the source wires 53 has one end bonded to the first electrode 11 (source electrode) of a semiconductor element 10 and the other end bonded to either the conductive substrate 22B or the pad portion 421 (band-shaped portion 421a) of the input terminal 42. The source wires 53 include those electrically connecting the first electrodes 11 of the semiconductor elements 10A and the conductive substrate 22B, and those electrically connecting the first electrodes 11 of the semiconductor elements 10B and the input terminal 42. The source wires 53 are one example of the “connecting members”. The diameter of each of the source wires 53 is not particularly limited, but may be no less than 25 μm and no greater than 500 μm, for example.

As shown in FIGS. 5 and 6, one of the pair of first connecting wires 54 connects the gate layer 24A and the signal terminal 45A (gate-signal input terminal), and the other connects the gate layer 24B and the signal terminal 45B (gate-signal input terminal). One of the first connecting wires 54 has one end bonded to the gate layer 24A and the other end bonded to the pad portion 451 of the signal terminal 45A so as to electrically connect them. The other one of the first connecting wires 54 has one end bonded to the gate layer 24B and the other end bonded to the pad portion 451 of the signal terminal 45B so as to electrically connect them.

As shown in FIGS. 5 and 6, one of the pair of second connecting wires 55 connects the detection layer 25A and the signal terminal 44A (source-signal detection terminal), and the other connects the detection layer 25B and the signal terminal 44B (source-signal detection terminal). One of the second connecting wires 55 has one end bonded to the gate layer 24A and the other end bonded to the pad portion 441 of the signal terminal 44A so as to electrically connect them. The other one of the second connecting wires 55 has one end bonded to the gate layer 24B and the other end bonded to the pad portion 441 of the signal terminal 44B so as to electrically connect them.

As shown in FIGS. 4, 5, and 10, the resin member 60 covers the semiconductor elements 10, the support substrate 20 (except for the reverse surfaces 212 of the insulating substrates 21A and 21B), portions of the terminals 41-43, 44A-47A, and 44B-47B, and the connecting members 50. The resin member 60 is made of epoxy resin, for example. As shown particularly in FIGS. 4, 5, and 10, the resin member 60 has a resin obverse surface 61, a resin reverse surface 62, and a plurality of resin side surfaces 631 to 634.

As shown particularly in FIG. 10, the resin obverse surface 61 and the resin reverse surface 62 are spaced apart from each other in the z direction. The resin obverse surface 61 faces in the z2 direction, and the resin reverse surface 62 faces in the z1 direction. As shown in FIG. 8, the resin reverse surface 62 has a frame shape surrounding the reverse surfaces 212 of the pair of insulating substrates 21A and 21B in plan view. The reverse surfaces 212 of the pair of insulating substrates 21A and 21B are exposed from the resin reverse surface 62. The resin side surfaces 631 to 634 are connected to the resin obverse surface 61 and the resin reverse surface 62 and sandwiched between them in the z direction. As shown in FIGS. 3 to 5, 7 and 8, the resin side surface 631 and the resin side surface 632 are spaced apart from each other in the x direction. The resin side surface 631 faces in the x1 direction, and the resin side surface 632 faces in the x2 direction. The two input terminals 41 and 42 protrude from the resin side surface 631, and the output terminal 43 protrudes from the resin side surface 632. As shown in FIGS. 3 to 5, 7 and 8, the resin side surface 633 and the resin side surface 634 are spaced apart from each other in the y direction. The resin side surface 633 faces in the y1 direction, and the resin side surface 634 faces in the y2 direction. The signal terminals 44A-47A and 44B-47B protrude from the resin side surface 633.

As shown in FIGS. 8 and 10, the resin member 60 includes a recess 65 recessed from the resin reverse surface 62 in the z direction. As shown in FIG. 8, the recess 65 has an annular shape surrounding the support substrate 20 in plan view. The shape of the recess 65, the arrangement thereof, the number of recesses 65, and so on are not limited to the examples shown in FIGS. 8 and 10. Note that the recess 65 may not be formed in the resin member 60.

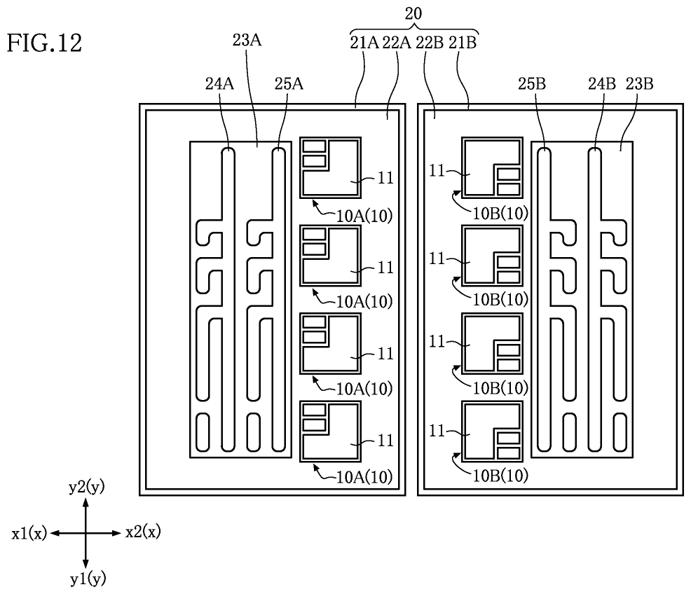

Next, a method for manufacturing the semiconductor device A1 will be described with reference to FIGS. 12 to 16.

First, as shown in FIG. 12, a support substrate 20 is prepared, and a plurality of semiconductor elements 10 are mounted on the support substrate 20. The support substrate 20 includes a pair of insulating substrates 21A and 21B, and a pair of conductive substrates 22A and 22B. The conductive substrate 22A is provided on the insulating substrate 21A, and the conductive substrate 22B is provided on the insulating substrate 21B. An insulating layer 23A, a gate layer 24A, and a detection layer 25A are formed on the conductive substrate 22A, and an insulating layer 23B, a gate layer 24B, and a detection layer 25B are formed on the conductive substrate 22B. Semiconductor elements 10A, which are included in the semiconductor elements 10, are bonded on the conductive substrate 22A of the support substrate 20 via a conductive bonding member such as solder. Similarly, semiconductor elements 10B, which are included in the semiconductor elements 10, are bonded on the conductive substrate 22B of the support substrate 20 via a conductive bonding member such as solder.

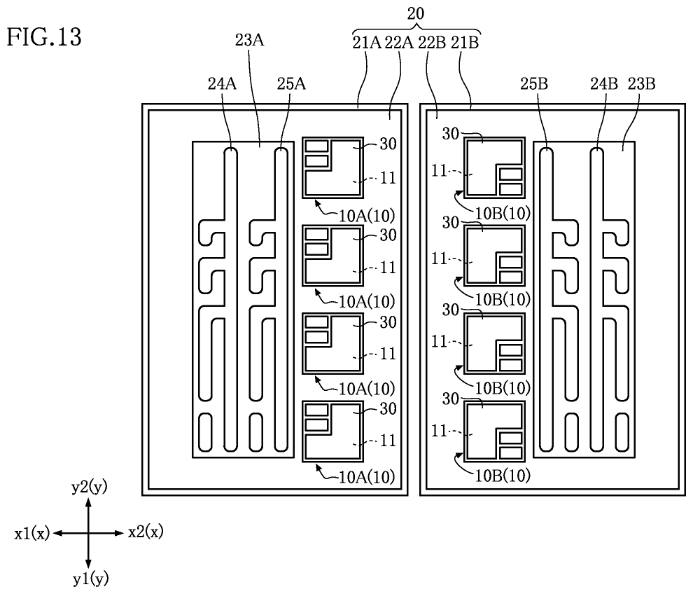

Next, as shown in FIG. 13, metal plates 30 are bonded to first electrodes 11 of the semiconductor elements 10 by solid-phase diffusion. In a step of solid-phase diffusion bonding (solid-phase diffusion bonding step), the metal plates 30 are first brought into contact with the first electrodes 11 of the semiconductor elements 10. At this point, surface layers 112 of the first electrodes 11 and first metal layers 32 of the metal plates 30 are brought into contact with each other. The surface layers 112 and the first metal layers 32 are then bonded to each other by solid-phase diffusion. Conditions of solid-phase diffusion may include a bonding temperature of 330° C. and a bonding pressure of 65 MPa. As the conditions of solid-phase diffusion, it is sufficient if the bonding temperature is set in the range of 250° C. to 350° C. inclusive, and the bonding pressure in the range of 30 MPa to 80 MPa inclusive. As such, the surface layers 112 of the first electrodes 11 and the first metal layers 32 of the metal plates 30 are bonded to each other by solid-phase diffusion. It is assumed that the solid-phase diffusion takes place in the atmosphere, but it may take place in a vacuum. Through the above steps, the metal plates 30 are bonded to the first electrodes 11.

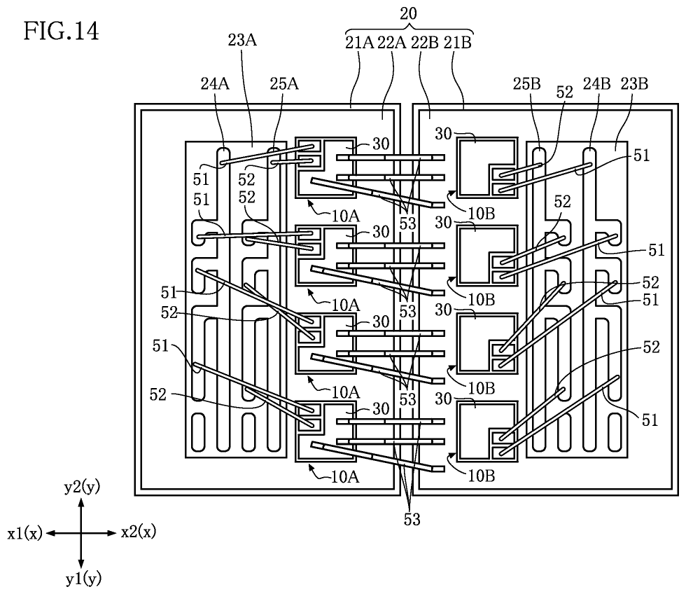

Next, as shown in FIG. 14, a plurality of gate wires 51, a plurality of detection wires 52, and a subset of source wires 53 are bonded. Each of the gate wires 51 is bonded to the second electrode 12 (gate electrode) of a semiconductor element 10 and either one of the pair of gate layers 24A and 24B. Each of the detection wires 52 is bonded to the third electrode (source sense electrode) of a semiconductor element 10 and either one of the pair of detection layers 25A and 25B. Each of the source wires 53 is bonded to the metal plate 30 formed on a semiconductor element 10A and the conductive substrate 22B. It is acceptable whether the source wires 53 are first bonded to the metal plates 30 or the conductive substrate 22B; however, it is preferable that the source wires 53 be first bonded to the metal plates 30. Bonding methods for the gate wires 51, the detection wires 52, and the subset of source wires 53 are not particularly limited. For example, the gate wires 51 and the detection wires 52 may be bonded by ball bonding using a capillary or stitch bonding, and the source wires 53 may be bonded by wedge bonding using a wedge tool.

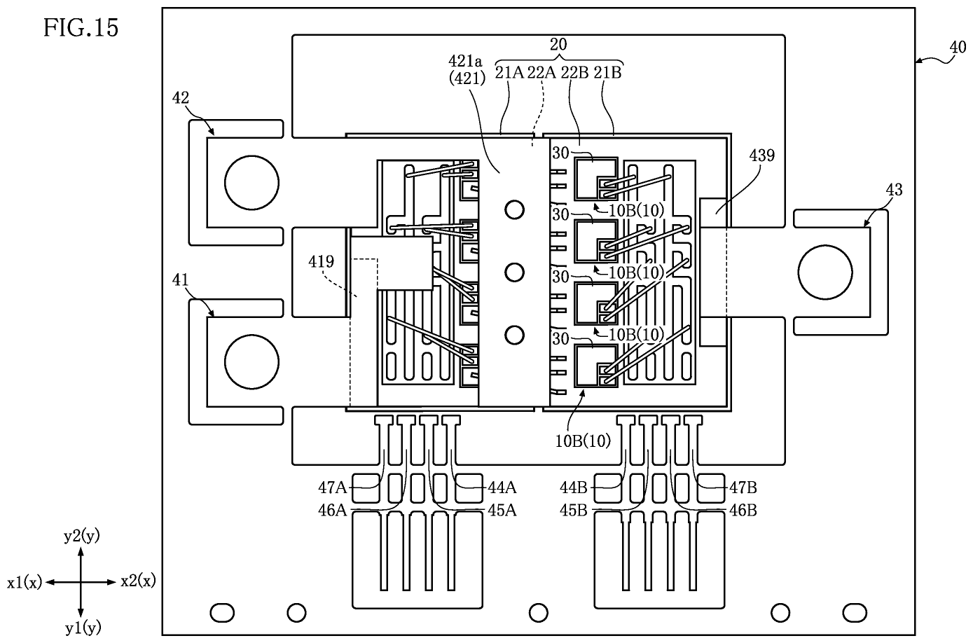

Next, as shown in FIG. 15, a lead frame 40 is placed on the support substrate 20. The lead frame 40 includes two input terminals 41 and 42, an output terminal 43, and a plurality of signal terminals 44A-47A and 44B-47B. In the lead frame 40, the two input terminals 41 and 42, the output terminal 43, and the signal terminals 44A-47A and 44B-47B are connected to each other. In a step of placing the lead frame 40 on the support substrate 20, the input terminal 41 is bonded to the conductive substrate 22A via a block member 419, and the output terminal 43 is bonded to the conductive substrate 22B via a block member 439. At this point, since the two input terminals 41 and 42, the output terminal 43, and the signal terminals 44A-47A and 44B-47B are connected to each other in the lead frame 40, the input terminal 42 and the signal terminals 44A-47A and 44B-47B, which are not bonded to the support substrate 20, are supported in a state of being away from the support substrate 20.

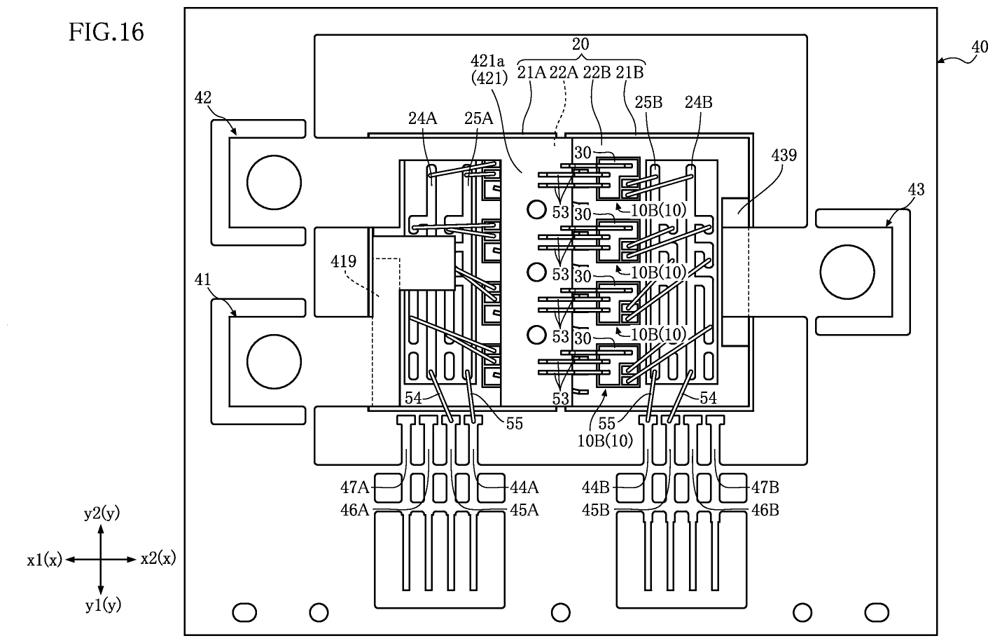

Next, the remaining source wires 53 are bonded as shown in FIG. 16. Each of the remaining source wires 53 is bonded to the metal plate 30 of a semiconductor element 10B and a pad portion 421 (band-shaped portion 421a) of the input terminal 42. It is acceptable whether the source wires 53 are first bonded to the metal plates 30 or the band-shaped portion 421a of the pad portion 421; however, it is preferable that the source wires 53 be first bonded to the metal plates 30. The source wires 53 are bonded by wedge bonding using a wedge tool. As shown in FIG. 16, a pair of first connecting wires 54 and a pair of second connecting wires 55 are also bonded. One of the pair of first connecting wires 54 is bonded to the gate layer 24A and the signal terminal 45A, and the other is bonded to the gate layer 24B and the signal terminal 45B. One of the pair of second connecting wires 55 is bonded to the detection layer 25A and the signal terminal 44A, and the other is bonded to the detection layer 25B and the signal terminal 44B. Bonding methods for the remaining source wires 53, the pair of first connecting wires 54, and the pair of second connecting wires 55 are not particularly limited. For example, the source wires 53 may be bonded by wedge bonding using a wedge tool, and the pair of first connecting wires 54 and the pair of second connecting wires 55 may be bonded by ball bonding using a capillary or stitch bonding.

Next, a resin member 60 is formed. For example, the resin member 60 is formed with the use of a well-known transfer molding machine or a well-known compression molding machine. The resin member 60 is made of an insulating epoxy resin, for example. In a step of forming the resin member 60, the resin member 60 is formed to cover the semiconductor elements 10, a portion of the support substrate 20, the metal plates 30, portions of the terminals 41-43, 44A-47A, and 44B-47B, the gate wires 51, the detection wires 52, the source wires 53, the pair of first connecting wires 54, and the pair of second connecting wires 55. The lead frame 40 is partially exposed from the formed resin member 60.

Next, portions of the lead frame 40 exposed from the resin member 60 are cut off. The lead frame 40 is then divided into the input terminal 41, the input terminal 42, the output terminal 43, and the signal terminals 44A-47A and 44B-47B, and the signal terminals 44A-47A and 44B-47B are bent appropriately.

The semiconductor device A1 as shown in FIGS. 1 to 11 is formed through the steps described above. The manufacturing method of the semiconductor device A1 described above is merely an example, and the present disclosure is not limited to this. For example, although it has been described that the solid-phase diffusion bonding step is performed after the semiconductor elements 10 are mounted on the support substrate 20, the solid-phase diffusion bonding step may be performed before the semiconductor elements 10 are mounted on the support substrate 20.

The following describes the operation and advantages of the semiconductor device A1.

The semiconductor device A1 includes the metal plates 30. The metal plates 30 are provided on the first electrodes 11. Some of the connecting members 50 (source wires 53) are bonded to the metal plates 30. In this configuration, the metal plates 30 are positioned between the first electrodes 11 and the connecting members 50. As such, the load on the first electrodes 11 is suppressed more than if the connecting members 50 were bonded directly to the first electrodes 11. In other words, damage to the first electrodes 11 is suppressed, thus resulting in less breakage of the first electrodes 11. Accordingly, the semiconductor device A1 can suppress breakage of the semiconductor elements 10 and has improved reliability.

In the semiconductor device A1, the source wires 53 (connecting members 50) are bonding wires which are made of a metal containing Cu. In other words, the source wires 53 (connecting members 50) are copper wires. Although copper wires can reduce electric resistance and thermal resistance simultaneously as compared to aluminum wires, the copper wires are harder than aluminum wires and cause more damage to the semiconductor elements 10. In other words, when copper wires are used as the source wires 53 (connecting members 50) and bonded to the first electrodes 11 directly, the semiconductor elements 10 become more prone to damage, and breakage (such as cracks) of the semiconductor elements 10 will be more noticeable. In view of this, the semiconductor device A1 uses the metal plates 30 to suppress damage to the first electrodes 11 that may occur during the bonding of the source wires 53. As such, the metal plates 30 can advantageously suppress breakage of the semiconductor elements 10 when copper wires are used as the source wires 53 (connecting members 50). In a semiconductor device different from the semiconductor device A1, the first electrodes 11 may be made of Cu with an increased thickness of about 5 to 50 μm in the z direction, so that breakage of the first electrodes 11 can be suppressed while allowing bonding of the connecting members 50 made of copper wires. In this case, however, the semiconductor elements 10 including the first electrodes 11 will have a special configuration that may lead to an increase of manufacturing cost. On the other hand, the semiconductor device A1 includes the metal plates 30 between the first electrodes 11 and the connecting members 50. As such, the semiconductor elements 10 do not need to have a special configuration. Accordingly, the semiconductor device A1 can suppress breakage of the semiconductor elements 10 while suppressing an increase of the manufacturing cost.

In the semiconductor device A1, the metal plates 30 and the first electrodes 11 are bonded to each other by solid-phase diffusion. In a semiconductor device different from the semiconductor device A1, the metal plates 30 (metal base members 31) may be bonded to the first electrodes 11 with a silver baking material or the like. In this case, a silver baking material or the like may be provided in advance on the surfaces of the metal plates 30 (metal base members 31) that face in the z1 direction. The metal plates 30 on which a silver baking material or the like is formed as described above are expensive because a paste-like silver baking material needs to kept in a dry state. In the semiconductor device A1, on the other hand, the manufacturing cost is relatively low because the metal plates 30 are produced by forming the first metal layers 32 on the metal base members 31 by sputtering or vacuum vapor deposition. Accordingly, the semiconductor device A1 can suppress breakage of the semiconductor elements 10 while suppressing an increase of the manufacturing cost.

In the semiconductor device A1, each of the metal plates 30 has a configuration in which the first metal layer 32 is formed on the metal base member 31. Each of the first electrodes 11 has a configuration in which the base layer 111 and the surface layer 112 are stacked on each other. When the metal plate 30 is bonded to the first electrode 11 by solid-phase diffusion, the solid-phase diffusion is caused to occur under a predetermined condition (e.g., a temperature of 330° C. and a pressure of 65 MPa) with the first metal layer 32 and the base layer 111 in contact with each other. With this configuration, the molecular binding portion R2 (non-interface portion R2) is formed between the surface layer 112 of the first electrode 11 and the first metal layer 32 of the metal plate 30. As such, the semiconductor device A1 allows for the solid-phase diffusion bonding between the first electrode 11 and the metal plate 30. Furthermore, the molecular binding portion R2 can improve the bonding strength between the first electrode 11 and the metal plate 30.

In the semiconductor device A1, the metal plates 30 include the respective metal base members 31, and each of the metal base members 31 has a thickness (dimension in the z direction) of no less than 30 μm and no greater than 200 μm. The configuration as described above can ensure a reasonable thickness for each metal plate 30. This, as a result, can suppress damage to the first electrodes 11 caused by the load generated when the connecting members 50 are bonded to the metal plates 30. Accordingly, the semiconductor device A1 can suppress breakage of the semiconductor elements 10 and has improved reliability.

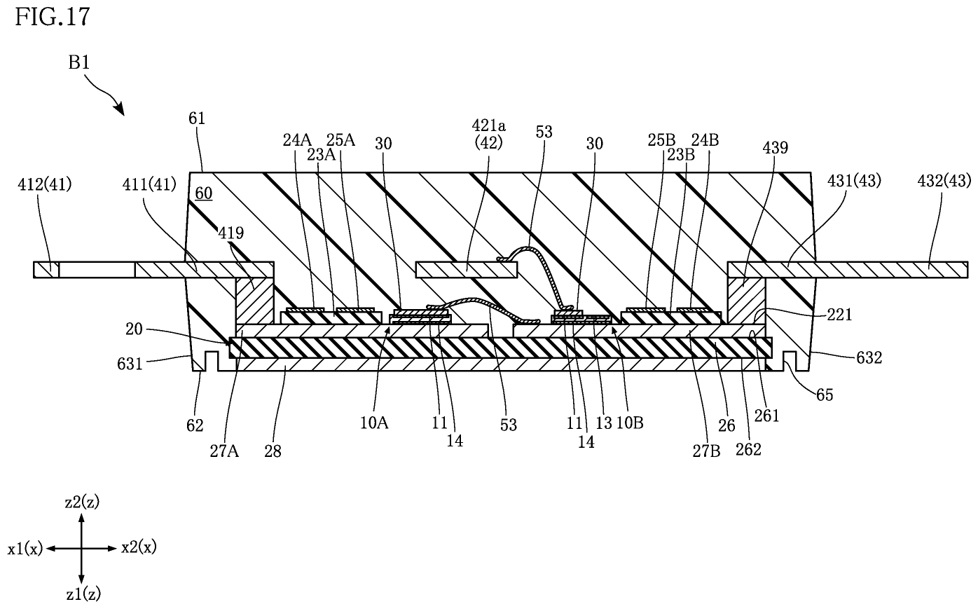

FIG. 17 shows a semiconductor device B1 according to a second embodiment. FIG. 17 is a cross-sectional view showing the semiconductor device B1, where the cross section shown in FIG. 17 corresponds to the cross section shown in FIG. 10.

The semiconductor device B1 is different from the semiconductor device A1 in the configuration of the support substrate 20. The support substrate 20 of the semiconductor device B1 is a direct bonded copper (DBC) substrate. The support substrate 20 may be a direct bonded aluminum (DBA) substrate instead of a DBC substrate. As shown in FIG. 17, the support substrate 20 of the semiconductor device B1 includes an insulating substrate 26, a pair of obverse-surface metal layers 27A and 27B, and a reverse-surface metal layer 28.

As with the insulating substrates 21A and 21B, the insulating substrate 26 is made of a ceramic material having excellent thermal conductivity, for example. The insulating substrate 26 has a rectangular shape in plan view, for example. As shown in FIG. 17, the insulating substrate 26 has an obverse surface 261 and a reverse surface 262. The obverse surface 261 and the reverse surface 262 are spaced apart from each other in the z direction. The obverse surface 261 faces in the z2 direction, and the reverse surface 262 faces in the z1 direction.

As shown in FIG. 17, the pair of obverse-surface metal layers 27A and 27B are formed on the obverse surface 261 of the insulating substrate 26. The material of the pair of obverse-surface metal layers 27A and 27B is Cu, for example. The material may be Al instead of Cu. The pair of obverse-surface metal layers 27A and 27B are spaced apart from each other in the x direction. The obverse-surface metal layer 27A is offset in the x1 direction relative to the obverse-surface metal layer 27B. As with the conductive substrate 22A, a plurality of semiconductor elements 10A are mounted on the obverse-surface metal layer 27A. As with the conductive substrate 22B, a plurality of semiconductor elements 10B are mounted on the obverse-surface metal layer 27B. The obverse-surface metal layers 27A and 27B are thinner than the conductive substrates 22A and 22B. In the present embodiment, the obverse-surface metal layer 27A is an example of the “first conductive member”, and the obverse-surface metal layer 27B is an example of the “second conductive member”.

The reverse-surface metal layer 28 is formed on the reverse surface 262 of the insulating substrate 26. The reverse-surface metal layer 28 is made of the same material as the obverse-surface metal layers 27A and 27B. The reverse-surface metal layer 28 may be covered with the resin member 60. Alternatively, the surface of the reverse-surface metal layer 28 facing in the z1 direction may be exposed from the resin member 60 (resin reverse surface 62).

The configuration of the support substrate 20 in the semiconductor device B1 may be modified as follows. For example, the insulating substrate 26 may not be a single insulating substrate, but may be divided for each of the pair of obverse-surface metal layers 27A and 27B instead. In other words, as is the case with the semiconductor device A1, the insulating substrate 26 may be divided into two insulating substrates, and the pair of obverse-surface metal layers 27A and 27B may be formed on the respective insulating substrates. Furthermore, the reverse-surface metal layer 28 may not be a single reverse-surface metal layer, but may be divided into two reverse-surface metal layers instead. In this case, the two reverse-surface metal layers are spaced apart from each other in the x direction, and overlap with the pair of the obverse-surface metal layers 27A and 27B, respectively, in plan view. Furthermore, the pair of conductive substrates 22A and 22B described above may be mounted on the pair of the obverse-surface metal layers 27A and 27B, respectively.

Aside from the configuration described above, the semiconductor device B1 is configured in the same manner as the semiconductor device A1. That is, in each of the semiconductor elements 10 of the semiconductor device B1, a metal plate 30 is bonded to a first electrode 11 by solid-phase diffusion, and source wires 53 are bonded to the metal plate 30.

The semiconductor device B1 is similar to the semiconductor device A1 in that the metal plates 30 are arranged on the first electrodes 11 of the semiconductor elements 10. Some of the connecting members 50 (source wires 53) are bonded to the metal plates 30. In this configuration, the metal plates 30 are positioned between the first electrodes 11 and the connecting members 50. As such, damage to the first electrodes 11 is suppressed more than if the connecting members 50 were bonded directly to the first electrodes 11. Accordingly, as with the semiconductor device A1, the semiconductor device B1 can also suppress breakage of the semiconductor elements 10 and has improved reliability.

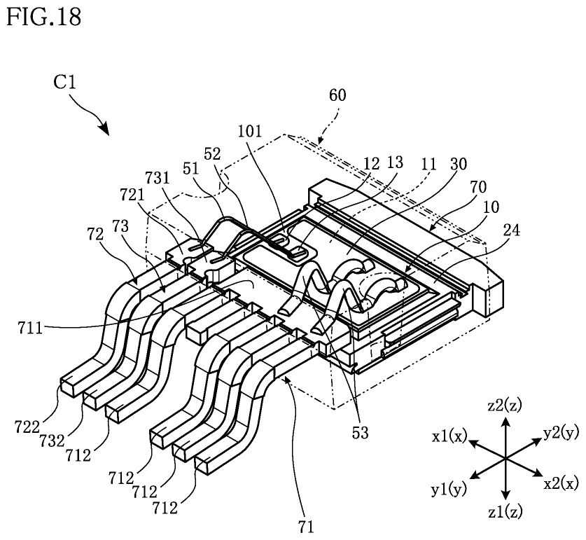

FIGS. 18 to 20 show a semiconductor device C1 according to a third embodiment. The semiconductor device C1 includes a semiconductor element 10, a metal plate 30, a plurality of connecting members 50, a resin member 60, and a lead frame 70. The connecting members 50 include a gate wire 51, a detection wire 52, and a plurality of source wires 53.

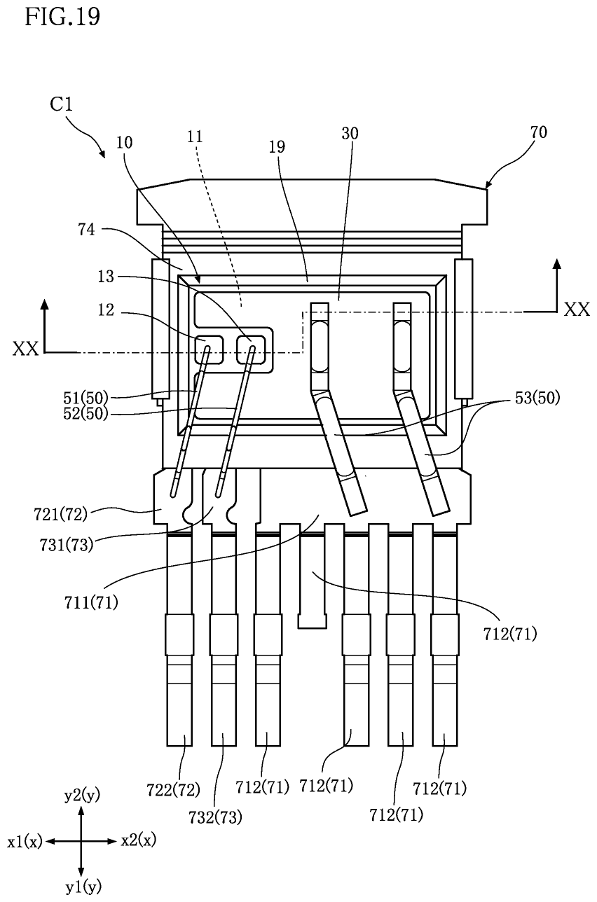

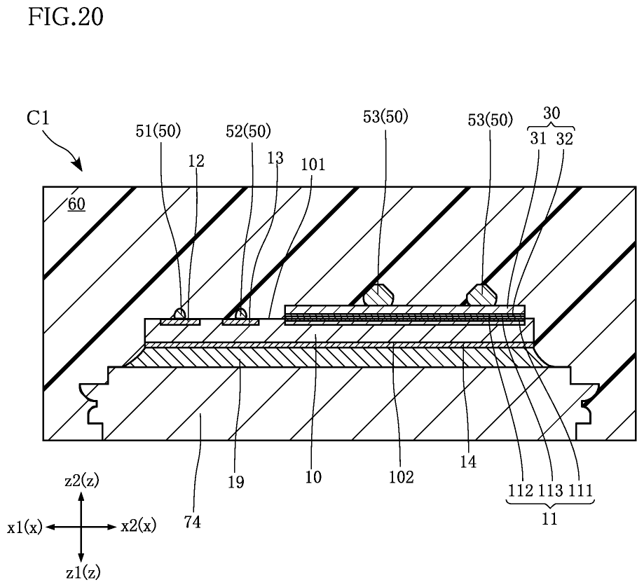

FIG. 18 is a perspective view showing the semiconductor device C1. In FIG. 18, the resin member 60 is indicated by an imaginary line (two-dot chain line). FIG. 19 is a plan view showing the semiconductor device C1. The resin member 60 is omitted in FIG. 19. FIG. 20 is a cross-sectional view along line XX-XX in FIG. 19.

As shown in FIGS. 18 to 20, the semiconductor device C1 is configured as a discrete component including a single semiconductor element 10. In the example shown in FIG. 18, the semiconductor device C1 has a transistor outline (TO) package structure.

The lead frame 70 has the semiconductor element 10 mounted thereon, and is electrically connected to the semiconductor element 10. The lead frame 70 can be mounted on the circuit board of an electronic device or the like, and thereby forms a conductive path between the semiconductor element 10 and the circuit board. The lead frame 70 is made of a conductive material. In the present embodiment, the conductive material is Cu, for example. However, it may be another conductive material such as Ni, a Cu—Ni alloy, or Alloy 42. The lead frame 70 is made of a thin metal plate made of Cu, for example, which has a rectangular shape in plan view. The metal plate is formed into an appropriate shape through a process such as punching, cutting, or bending. As shown in FIGS. 18 to 20, the lead frame 70 includes a first lead 71, a second lead 72, a third lead 73, and a die pad 74. The first lead 71, the second lead 72, the third lead 73, and the die pad 74 are spaced apart from each other.

The first lead 71 is electrically connected to a first electrode 11 (source electrode) of the semiconductor element 10. The first lead 71 is electrically connected to the first electrode 11 via the source wires 53. The first lead 71 is an example of the “second conductive member”. As shown in FIG. 19, the first lead 71 includes a wire bonding portion 711 and a plurality of terminal portions 712.

One end of each of the source wires 53 is bonded to the wire bonding portion 711. The wire bonding portion 711 is covered with the resin member 60.

The terminal portions 712 are connected to the wire bonding portion 711 and partially exposed from the resin member 60. The terminal portions 712 have the same shape except one terminal portion. The terminal portions 712 overlap with each other, as viewed in the x direction. The terminal portions 712 can be bonded to a circuit board to function as the source terminals of the semiconductor device C1.

The second lead 72 is electrically connected to a second electrode 12 (gate electrode) of the semiconductor element 10. The second lead 72 is electrically connected to the second electrode 12 via the gate wire 51. As shown in FIG. 19, the second lead 72 includes a wire bonding portion 721 and a terminal portion 722.

One end of the gate wire 51 is bonded to the wire bonding portion 721. The wire bonding portion 721 is covered with the resin member 60.

The terminal portion 722 is connected to the wire bonding portion 721 and partially exposed from the resin member 60. The terminal portion 722 is partially bent at the portion exposed from the resin member 60. The terminal portion 722 overlaps with the terminal portions 712 as viewed in the x direction. The terminal portion 722 can be bonded to a circuit board as the gate terminal of the semiconductor device C1.

The third lead 73 is electrically connected to a third electrode 13 (source sense electrode) of the semiconductor element 10. The third lead 73 is electrically connected to the third electrode 13 via the detection wire 52. As shown in FIG. 19, the third lead 73 includes a wire bonding portion 731 and a terminal portion 732.

One end of the detection wire 52 is bonded to the wire bonding portion 731. The wire bonding portion 731 is covered with the resin member 60.

The terminal portion 732 is connected to the wire bonding portion 731 and partially exposed from the resin member 60. The terminal portion 732 is partially bent at the portion exposed from the resin member 60. The terminal portion 732 overlaps with the terminal portions 712 and the terminal portion 722 as viewed in the x direction. The terminal portion 732 is sandwiched between the terminal portions 712 and the terminal portion 722 in the x direction. The terminal portion 732 can be bonded to a circuit board as the source sense terminal of the semiconductor device C1.

As shown in FIGS. 18 to 20, the semiconductor element 10 is mounted on the die pad 74. A portion of the die pad 74 is covered with the resin member 60, and another portion of the die pad 74 is exposed from the resin member 60. The die pad 74 is electrically connected to a fourth electrode 14 (drain electrode) of the semiconductor element 10 via a conductive bonding member 19 (e.g., solder, metal paste, or sintered metal). The surface of the die pad 74 facing in the z1 direction is exposed from the resin member 60. The die pad 74 can be bonded to a circuit board as the drain terminal of the semiconductor device C1. The die pad 74 is an example of the “first conductive member”.

As shown in FIG. 18, the metal plate 30 of the semiconductor device C1 is also similarly bonded to the first electrode 11 (semiconductor element 10) by solid-phase diffusion. The source wires 53 are bonded to the metal plate 30. As shown in FIG. 18, each of the source wires 53 is bonded to the metal plate 30 twice and then bonded to the wire bonding portion 711 (first lead 71). Bonding as described above can improve the bonding strength between the metal plate 30 and the source wires 53 and smoothen the flow of a source current. Such a bonding method is also applicable to the metal plates 30 in the first and second embodiments.

The semiconductor device C1 is similar to the semiconductor devices A1 and B1 in that the metal plate 30 is arranged on the first electrode 11 of the semiconductor element 10. Some of the connecting members 50 (source wires 53) are bonded to the metal plate 30. In this configuration, the metal plate 30 is positioned between the first electrode 11 and the connecting members 50. As such, damage to the first electrode 11 is suppressed more than if the connecting members 50 were bonded directly to the first electrode 11. Accordingly, as with the semiconductor devices A1 and B1, the semiconductor device C1 can also suppress breakage of the semiconductor element 10 and has improved reliability.

Although the third embodiment has given an example where the semiconductor device C1 has a TO package structure, the present disclosure is not limited to this. For example, the semiconductor device C1 may be configured as another well-known package referred to as small outline no-lead (SON), quad flat no-lead (QFN), small outline package (SOP), or quad flat package (QFP).

Next, variations applicable to the first to third embodiments are described. In the following examples, the variations are applied to the semiconductor device A1 in the first embodiment. However, the variations are also applicable to the semiconductor device B1 of the second embodiment and the semiconductor device C1 of the third embodiment.

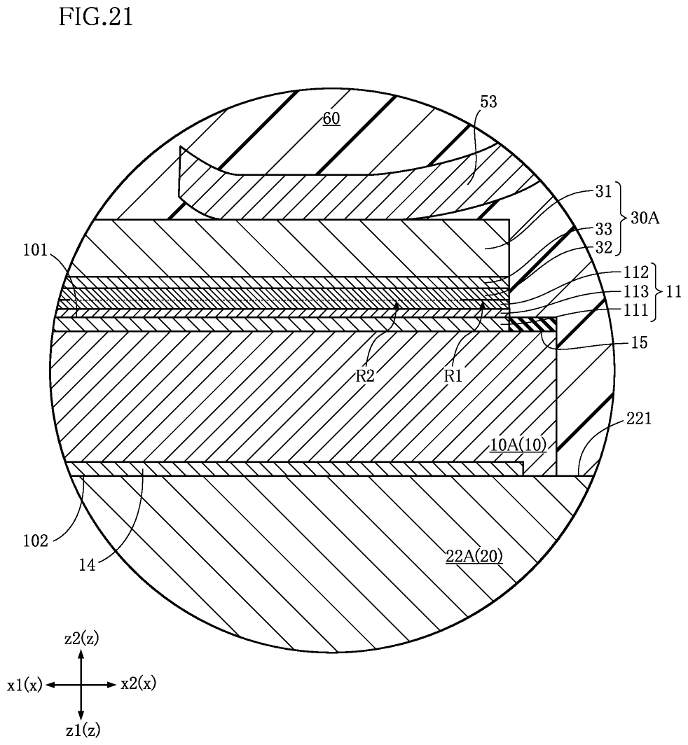

In the first to third embodiments, the configuration of each metal plate 30 is not limited to the above examples. Examples of other configurations of the metal plate 30 are described below with reference to FIGS. 21 to 23.

FIG. 21 shows a first variation of the metal plate 30. In the following description, the metal plate 30 according to the first variation is referred to as a metal plate 30A. FIG. 21 is a partially enlarged cross-sectional view corresponding to FIG. 11, and shows the configuration of the metal plate 30A. As shown in FIG. 21, the metal plate 30A is different from the metal plate 30 (see FIG. 11) in further including a second metal layer 33.

The second metal layer 33 is interposed between the metal base member 31 and the first metal layer 32 in the z direction. The material of the second metal layer 33 is Al, for example. The material is not limited to Al, and may be another material softer than the metal base member 31. For example, with Vickers hardness as an indicator of softness, the second metal layer 33 may be made of any material having a Vickers hardness lower than the material of the metal base member 31. In one example, it suffices for the material of the second metal layer 33 to have a Vickers hardness of 30 or less. It is possible to use Young's modulus as an indicator of softness, instead of Vickers hardness. The second metal layer 33 may be formed by sputtering or vacuum vapor deposition, for example.

If the metal base member 31 of the metal plate 30 is made of Cu and the semiconductor element 10 is made of a semiconductor material, then the difference in coefficient of linear thermal expansion between the metal base member 31 and the semiconductor element 10 will be large. As a result, when the semiconductor element 10 is energized and generates heat, a large thermal stress is applied to the first metal layer 32 and the surface layer 112 that are provided between the metal base member 31 and the semiconductor element 10. The thermal stress is a factor of causing cracks in the first metal layer 32 and the surface layer 112. In view of this, the second metal layer 33 is provided between the metal base member 31 and the first metal layer 32, so that the second metal layer 33 functions as a buffer that absorbs the thermal stress. As such, the metal plate 30A can be used to suppress creation of cracks in the first metal layer 32 and the surface layer 112.

In the first variation described above, the second metal layer 33 is made of a material having a Vickers hardness lower than the metal base member 31. However, the present disclosure is not limited to this, and the second metal layer 33 may be made of a material having a coefficient of thermal expansion between those of the metal base member 31 and the first metal layer 32. Even in such a case, the second metal layer 33 can alleviate the thermal stress to suppress cracks generated in the first metal layer 32 and the surface layer 112.

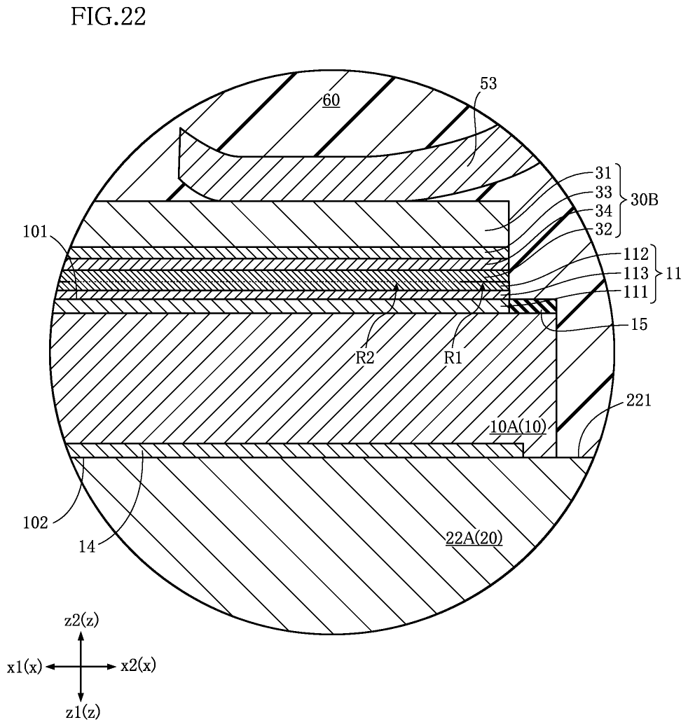

FIG. 22 shows a second variation of the metal plate 30. In the following description, the metal plate 30 according to the second variation is referred to as a metal plate 30B. FIG. 22 is a partially enlarged cross-sectional view corresponding to FIG. 11, and shows the configuration of the metal plate 30B. As shown in FIG. 22, the metal plate 30B is different from the metal plate 30A (see FIG. 21) in further including a barrier layer 34.

The barrier layer 34 is interposed between the first metal layer 32 and the second metal layer 33 in the z direction. The barrier layer 34 is provided to prevent the material (e.g., Ag) of the metal base member 31 from diffusing into the second metal layer 33 (which is made of Al). The material of the barrier layer 34 is Ni, for example. The material is not limited to Ni, and it may be any material having a smaller diffusion coefficient (e.g., Pd, Ti, Cr, W, or Ir) than each of the materials of the first metal layer 32 and the second metal layer 33. However, it is preferable that the material be Ni in terms of cost, versatility, process difficulty, and thermal conductivity, for example. The barrier layer 34 may be formed by sputtering or vacuum vapor deposition, for example.

According to the metal plate 30B, the barrier layer 34 functions as an anti-diffusion layer to prevent the second metal layer 33 from diffusing into the first metal layer 32.

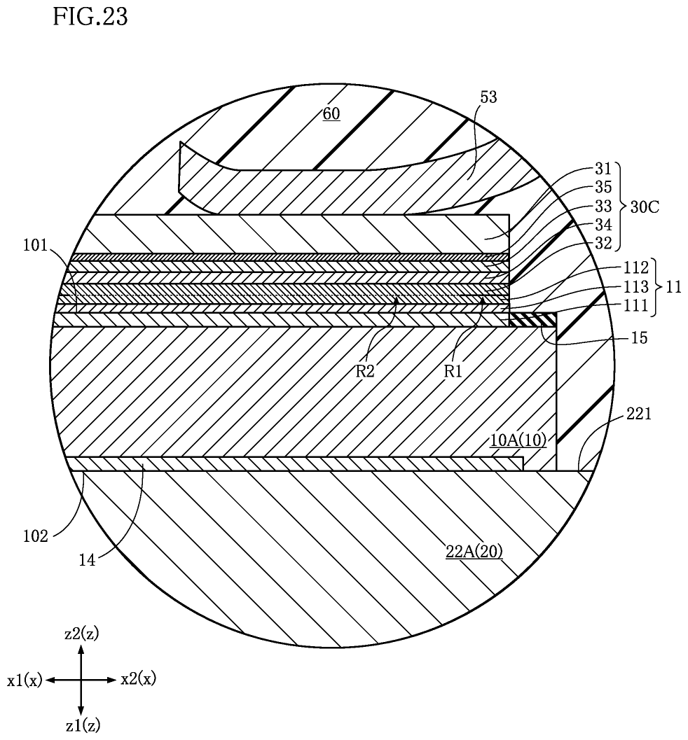

FIG. 23 shows a third variation of the metal plate 30. In the following description, the metal plate 30 according to the third variation is referred to as a metal plate 30C. FIG. 23 is a partially enlarged cross-sectional view corresponding to FIG. 11, and shows the configuration of the metal plate 30C. As shown in FIG. 23, the metal plate 30C is different from the metal plate 30B (see FIG. 22) in further including an adhesive layer 35.

The adhesive layer 35 is interposed between the metal base member 31 and the second metal layer 33 in the z direction. The adhesive layer 35 is provided to strengthen the adhesion between the metal base member 31 and the second metal layer 33. The material of the adhesive layer 35 is Ni, for example. The material may be Ti instead of Ni. The adhesive layer 35 may be formed by sputtering or vacuum vapor deposition, for example.

According to the metal plate 30C, the adhesive layer 35 functions as an anti-peeling layer to prevent peeling at the interface between the metal base member 31 and the second metal layer 33.

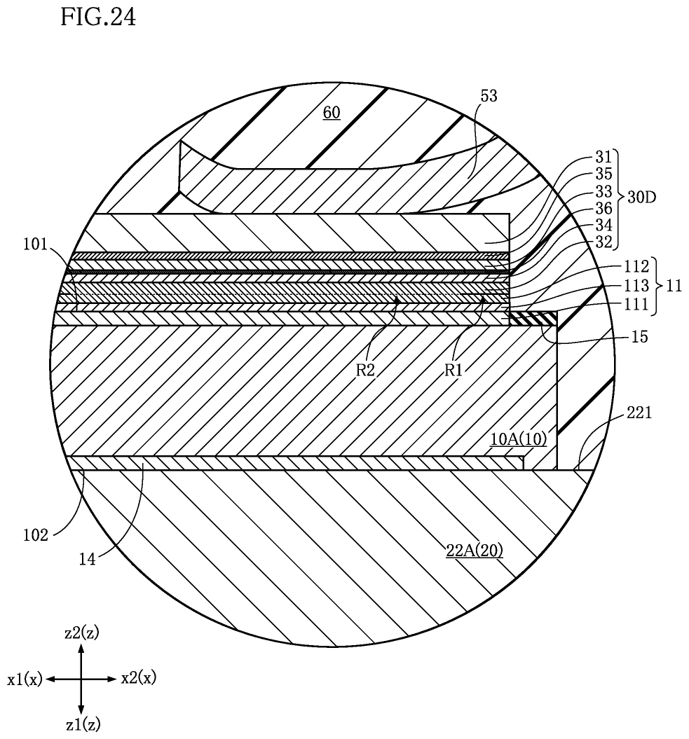

FIG. 24 shows a fourth variation of the metal plate 30. In the following description, the metal plate 30 according to the fourth variation is referred to as a metal plate 30D. FIG. 24 is a partially enlarged cross-sectional view corresponding to FIG. 11, and shows the configuration of the metal plate 30D. As shown in FIG. 24, the metal plate 30D is different from the metal plate 30C (see FIG. 23) in further including an intermediate layer 36.

The intermediate layer 36 is interposed between the second metal layer 33 and the barrier layer 34 in the z direction. The intermediate layer 36 improves the adhesion between the second metal layer 33 and the barrier layer 34. When the second metal layer 33 is made of Al and the barrier layer 34 is made of Ni, the intermediate layer 36 may be made of Ti. The intermediate layer 36 may be formed by sputtering, for example. The intermediate layer 36 has a thickness (dimension in the z direction) of about 0.2 μm, for example.

According to the metal plate 30D, the intermediate layer 36 improves the adhesion between the second metal layer 33 and the barrier layer 34 and prevents peeling at the interface between the second metal layer 33 and the barrier layer 34.

In the example shown in FIG. 24, the intermediate layer 36 is interposed between the second metal layer 33 and the barrier layer 34. However, the present disclosure is not limited to this. For example, the intermediate layer 36 may be interposed between the second metal layer 33 and the adhesive layer 35, or may be interposed between the second metal layer 33 and the barrier layer 34 as well as between the second metal layer 33 and the adhesive layer 35.

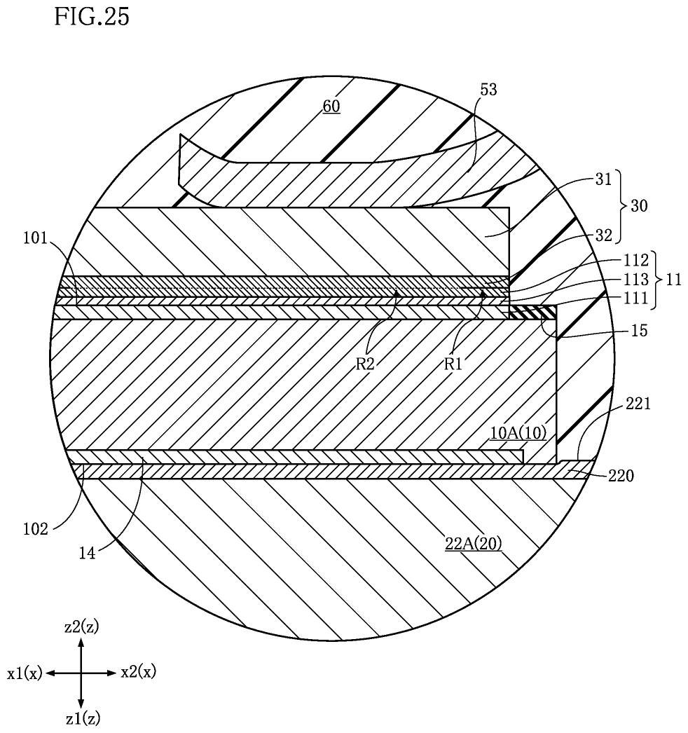

In the first to third embodiments, each of the semiconductor elements 10 is bonded to either the support substrate 20 or the lead frame 70 via a conductive bonding member, but the present disclosure is not limited to this. For example, each of the semiconductor elements 10 may be bonded to either the support substrate 20 or the lead frame 70 by solid-phase diffusion. FIG. 25 is a partially enlarged cross-sectional view showing a semiconductor device according to such a variation, and corresponds to FIG. 11 relating to the first embodiment (semiconductor device A1).

As shown in FIG. 25, the semiconductor device according to the present variation includes metal foils 220 made of Al, for example, on the respective surface layers of the conductive substrates 22A and 22B. The dimension of each of the metal foils 220 in the z direction is about 100 μm, for example. The semiconductor elements 10A and 10B are partially buried in the respective metal foils 220 due to the load applied when the semiconductor elements 10A and 10B are bonded to the metal foils 220 by solid-phase diffusion. For example, the semiconductor elements 10A and 10B are buried about 10 μm deep in the metal foils 220. The present variation makes it possible to perform two steps collectively, namely a step of bonding the semiconductor elements 10 to either the respective conductive substrates 22A and 22B or the lead frame 70 by solid-phase diffusion, and a step of bonding the metal plates 30 to the first electrodes 11 of the semiconductor elements 10 by solid-phase diffusion (solid-phase diffusion bonding step).

In the variation shown in FIG. 25, the semiconductor elements 10 in the semiconductor device A1 are bonded to the support substrate 20 (the conductive substrates 22A and 22B) by solid-phase diffusion. However, the present disclosure is not limited to this. As described above, the semiconductor elements 10 in the semiconductor device B1 may be bonded to the obverse-surface metal layers 27A and 27B by solid-phase diffusion, or the semiconductor element 10 in the semiconductor device C1 may be bonded to the lead frame 70 (die pad 74) by solid-phase diffusion. In these examples, a metal foil 220 is also similarly formed either on the surface layer of each of the obverse-surface metal layers 27A and 27B or on the surface layer of the die pad 74. Furthermore, the semiconductor elements 10 are partially buried in the metal foils 220.

In each of the metal plates 30 according to the first to third embodiments (and the variations thereof), at least the first metal layer 32 is stacked on the metal base member 31. However, the present disclosure is not limited to this. If the metal base member 31 of the metal plate 30 can be directly bonded to the first electrode 11 by solid-phase diffusion, the metal plate 30 may not include the first metal layer 32. Furthermore, the present disclosure is not limited to the example where each of the first electrodes 11 is formed by stacking at least the surface layer 112 on the base layer 111. If the base layer 111 can be directly bonded to the metal plate 30, the first electrode 11 may not include the surface layer 112. For example, if the metal base member 31 is made of a material containing Cu and the base layer 111 is also made of a material containing Cu, it is possible to cause solid-phase diffusion without forming the first metal layer 32 for the metal plate 30 and without forming the surface layer 112 for the first electrode 11.

In the first to third embodiments, the source wires 53 in the connecting members 50 are bonding wires. However, the present disclosure is not limited to this. For example, the source wires 53 may be plate-like lead members. The lead members may be bonded to bonding targets by ultrasonic bonding. Accordingly, the metal plates 30 may be bonded to the first electrodes 11 by solid-phase diffusion, so that the first electrodes 11 are prevented from being damaged by the vibration or load during the ultrasonic bonding. In other words, it is possible to prevent damage of the semiconductor elements 10, thereby improving the reliability of the semiconductor device. Alternatively, the lead members may be bonded to the bonding targets by laser bonding. During the laser bonding, heat is generated by laser irradiation. If the heat reaches the bodies of the semiconductor elements 10, it may damage the semiconductor elements 10. Accordingly, the metal plates 30 may be bonded to the first electrodes 11 by solid-phase diffusion. This prevents the heat generated by laser irradiation from reaching the bodies of the semiconductor elements 10, and consequently prevents damage to the semiconductor elements 10 caused by the laser irradiation.

The semiconductor device and the method for manufacturing the semiconductor device according to the present disclosure are not limited to those in the above embodiments. Various design changes can be made to the specific configurations of the elements of the semiconductor device of the present disclosure, and to the specific processes in the method for manufacturing the semiconductor device according to the present disclosure. For example, the semiconductor device and the method for manufacturing the semiconductor device of the present disclosure include the embodiments according to the following clauses.

Clause 1.

A semiconductor device comprising:

a semiconductor element having an element obverse surface and an element reverse surface that are spaced apart from each other in a thickness direction, the element obverse surface being provided with an obverse surface electrode;

a first conductive member that faces the element reverse surface and to which the semiconductor element is bonded;

a second conductive member spaced apart from the first conductive member;

a connecting member electrically connecting the obverse surface electrode and the second conductive member; and

a metal plate interposed between the obverse surface electrode and the connecting member in the thickness direction,

wherein the obverse surface electrode and the metal plate are bonded to each other by solid-phase diffusion.

Clause 2.

The semiconductor device according to clause 1,

wherein the obverse surface electrode includes a base layer and a surface layer stacked in the thickness direction, and

the metal plate is bonded to the surface layer.

Clause 3.

The semiconductor device according to clause 2, wherein the obverse surface electrode includes an anti-diffusion layer sandwiched between the base layer and the surface layer in the thickness direction.

Clause 4.

The semiconductor device according to clause 3, wherein the anti-diffusion layer is made of a material having a smaller diffusion coefficient than respective materials of the base layer and the surface layer.

Clause 5.

The semiconductor device according to any of clauses 2 to 4, wherein the base layer is made of AlCu.

Clause 6.

The semiconductor device according to any of clauses 2 to 5, wherein the metal plate includes a metal base member and a first metal layer that are bonded to each other in the thickness direction,

the metal base member has a base-member obverse surface and a base-member reverse surface that are spaced apart from each other in the thickness direction,

the connecting member is bonded to the base-member obverse surface,

the first metal layer is formed on the base-member reverse surface, and

the first metal layer and the surface layer are bonded to each other by solid-phase diffusion.

Clause 7.

The semiconductor device according to clause 6, wherein the metal base member has a dimension of no less than 30 μm and no greater than 200 μm in the thickness direction.

Clause 8.

The semiconductor device according to clause 6 or 7, wherein a material of the metal base member contains copper.

Clause 9.

The semiconductor device according to any of clauses 6 to 8, wherein the first metal layer and the surface layer are each made of a material that can be bonded by solid-phase diffusion.

Clause 10.

The semiconductor device according to clause 9, wherein the first metal layer and the surface layer are each made of silver.

Clause 11.

The semiconductor device according to any of clauses 6 to 10, wherein an interface portion, which is a portion having an interface, and a bound portion resulting from solid-phase diffusion bonding are formed between the first metal layer and the surface layer.

Clause 12.

The semiconductor device according to any of clauses 6 to 11,

wherein the metal plate further includes a second metal layer interposed between the metal base member and the first metal layer in the thickness direction, and

the second metal layer has a Vickers hardness lower than the metal base member.

Clause 13.

The semiconductor device according to clause 12, wherein the second metal layer is made of Al.

Clause 14.

The semiconductor device according to clause 12 or 13, wherein the metal plate further includes an anti-diffusion layer interposed between the first metal layer and the second metal layer in the thickness direction.

Clause 15.

The semiconductor device according to clause 14, wherein the anti-diffusion layer is made of Ni.

Clause 16.

The semiconductor device according to clause 14 or 15, wherein the metal plate further includes an intermediate layer interposed between the second metal layer and the anti-diffusion layer in the thickness direction.

Clause 17.

The semiconductor device according to clause 16, wherein the intermediate layer is made of Ti.

Clause 18.

The semiconductor device according to any of clauses 1 to 17, wherein the metal plate has a dimension larger than the obverse surface electrode in the thickness direction.

Clause 19.

The semiconductor device according to any of clauses 1 to 18, wherein the connecting member is a metal bonding wire containing copper.

Clause 20.

The semiconductor device according to clause 19, wherein the bonding wire has a diameter of no less than 25 μm and no greater than 500 μm.

Clause 21.

The semiconductor device according to any of clauses 1 to 20, wherein the semiconductor element is a power semiconductor element.

Clause 22.

A method for manufacturing a semiconductor device including a semiconductor element and a conductive connecting member, the semiconductor element having an element obverse surface and an element reverse surface that are spaced apart from each other in a thickness direction, the semiconductor element having an obverse surface electrode provided on the element obverse surface, the conductive connecting member being electrically connected to the semiconductor element, the method comprising:

a solid-phase diffusion bonding step of bringing a metal plate into contact with the obverse surface electrode, and bonding the metal plate and the obverse surface electrode by solid-phase diffusion through heating and pressurizing; and

a bonding step of bonding the connecting member to the metal plate.

### REFERENCE NUMERALS

A1, B1, C1: Semiconductor device
10, 10A, 10B: Semiconductor element
101: Element obverse surface
102: Element reverse surface
11: First electrode
111: Base layer
112: Surface layer
113: Barrier layer
12: Second electrode
13: Third electrode
14: Fourth electrode
15: Insulating film
19: Conductive bonding member
20: Support substrate
21A, 21B: Insulating substrate
211: Obverse surface
212: Reverse surface
22A, 22B: Conductive substrate
220: Metal foil
221: Obverse surface
222: Reverse surface
261: Obverse surface
262: Reverse surface
23A, 23B: Insulating layer
24A, 24B: Gate layer
25A, 25B: Detection layer
26: Insulating substrate
27A, 27B: Obverse-surface metal layer
28: Reverse-surface metal layer
30, 30A, 30B, 30C: Metal plate
31: Metal base member
311: Base-member obverse surface
312: Base-member reverse surface
32: First metal layer
33: Second metal layer
34: Barrier layer
35: Adhesive layer
36: Intermediate layer
40: Lead frame
41: Input terminal
411: Pad portion
412: Terminal portion
419: Block member
42: Input terminal
421: Pad portion
421a: Band-shaped portion
421b: Connecting portion
422: Terminal portion
43: Output terminal
431: Pad portion
432: Terminal portion
439: Block member
44A-47A, 44B-47B: Signal terminal
441, 451, 461, 471: Pad portion
442, 452, 462, 472: Terminal portion
50: Connecting member
51: Gate wire
52: Detection wire
53: Source wire
54: First connecting wire
55: Second connecting wire
60: Resin member
61: Resin obverse surface
62: Resin reverse surface
631-634: Resin side surface
65: Recess
70: Lead frame
71: First lead
711, 721, 731: Wire bonding portion
712, 722, 732: Terminal portion
72: Second lead
73: Third lead
74: Die pad

1. A semiconductor device comprising:
a semiconductor element having an element obverse surface and an element reverse surface that are spaced apart from each other in a thickness direction, the element obverse surface being provided with an obverse surface electrode;
a first conductive member that faces the element reverse surface and to which the semiconductor element is bonded;
a second conductive member spaced apart from the first conductive member;
a connecting member electrically connecting the obverse surface electrode and the second conductive member; and
a metal plate interposed between the obverse surface electrode and the connecting member in the thickness direction,
wherein the obverse surface electrode and the metal plate are bonded to each other by solid-phase diffusion.

2. The semiconductor device according to claim 1,
wherein the obverse surface electrode includes a base layer and a surface layer stacked in the thickness direction, and
the metal plate is bonded to the surface layer.

3. The semiconductor device according to claim 2, wherein the obverse surface electrode includes an anti-diffusion layer sandwiched between the base layer and the surface layer in the thickness direction.

4. The semiconductor device according to claim 3, wherein the anti-diffusion layer is made of a material having a smaller diffusion coefficient than respective materials of the base layer and the surface layer.

5. The semiconductor device according to claim 2, wherein the base layer is made of AlCu.

6. The semiconductor device according to claim 2,
wherein the metal plate includes a metal base member and a first metal layer that are bonded to each other in the thickness direction,
the metal base member has a base-member obverse surface and a base-member reverse surface that are spaced apart from each other in the thickness direction,
the connecting member is bonded to the base-member obverse surface,
the first metal layer is formed on the base-member reverse surface, and
the first metal layer and the surface layer are bonded to each other by solid-phase diffusion.

7. The semiconductor device according to claim 6, wherein the metal base member has a dimension of no less than 30 μm and no greater than 200 μm in the thickness direction.

8. The semiconductor device according to claim 6, wherein a material of the metal base member contains copper.

9. The semiconductor device according to claim 6, wherein the first metal layer and the surface layer are each made of a material that can be bonded by solid-phase diffusion.

10. The semiconductor device according to claim 9, wherein the first metal layer and the surface layer are each made of silver.

11. The semiconductor device according to claim 6, wherein an interface portion, which is a portion having an interface, and a bound portion resulting from solid-phase diffusion bonding are formed between the first metal layer and the surface layer.

12. The semiconductor device according to claim 6,
wherein the metal plate further includes a second metal layer interposed between the metal base member and the first metal layer in the thickness direction, and
the second metal layer has a Vickers hardness lower than the metal base member.

13. The semiconductor device according to claim 12, wherein the second metal layer is made of Al.

14. The semiconductor device according to claim 12, wherein the metal plate further includes an anti-diffusion layer interposed between the first metal layer and the second metal layer in the thickness direction.

15. The semiconductor device according to claim 14, wherein the anti-diffusion layer is made of Ni.

16. The semiconductor device according to claim 14, wherein the metal plate further includes an intermediate layer interposed between the second metal layer and the anti-diffusion layer in the thickness direction.

17. The semiconductor device according to claim 16, wherein the intermediate layer is made of Ti.

18. The semiconductor device according to claim 1, wherein the metal plate has a dimension larger than the obverse surface electrode in the thickness direction.

19. The semiconductor device according to claim 1, wherein the connecting member is a metal bonding wire containing copper.

20. The semiconductor device according to claim 19, wherein the bonding wire has a diameter of no less than 25 μm and no greater than 500 μm.

21. The semiconductor device according claim 1, wherein the semiconductor element is a power semiconductor element.

22. A method for manufacturing a semiconductor device including a semiconductor element and a conductive connecting member, the semiconductor element having an element obverse surface and an element reverse surface that are spaced apart from each other in a thickness direction, the semiconductor element having an obverse surface electrode provided on the element obverse surface, the conductive connecting member being electrically connected to the semiconductor element, the method comprising:
a solid-phase diffusion bonding step of bringing a metal plate into contact with the obverse surface electrode, and bonding the metal plate and the obverse surface electrode by solid-phase diffusion through heating and pressurizing; and
a bonding step of bonding the connecting member to the metal plate.
